(19) United States
(12) Patent Application Publication
(10) Pub. No.: US 2009/0117491 A1
(43) Pub. Date: May 7, 2009

(54) RESOLUTION ENHANCEMENT TECHNIQUES COMBINING INTERFERENCE-ASSISTED LITHOGRAPHY WITH OTHER PHOTOLITHOGRAPHY TECHNIQUES

(75) Inventors: Rudolf Hendel, Los Gatos, CA (US); Zhilong Rao, Stanford, CA (US); Kuo-Shih Liu, Fremont, CA (US); Chris A. Mack, Austin, TX (US); John S. Petersen, Austin, TX (US); Shane Palmer, Austin, TX (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/199,273

(22) Filed: Aug. 27, 2008

Related U.S. Application Data
(60) Provisional application No. 60/969,280, filed on Aug. 31, 2007.
(60) Provisional application No. 60/969,230, filed on Aug. 31, 2007.

(51) Int. Cl. G03B 27/52; G03B 27/32; G03F 7/20; G03B 27/42

(52) U.S. Cl. 430/296; 355/77; 355/53; 355/27; 430/325

(57) ABSTRACT

Methods and systems are disclosed that provide multiple lithography exposures on a wafer, for example, using interference lithography and optical photolithography. Various embodiments may balance the dosage and exposure rates between the multiple lithography exposures to provide the needed exposure on the wafer. Other embodiments provide for assist features and/or may apply resolution enhancement to various exposures. In a specific embodiment, a wafer is first exposed using optical photolithography and then exposed using interference lithography.

### CROSS-REFERENCES TO RELATED APPLICATIONS

This application is a nonprovisional, and claims the benefit, of U.S. Provisional Patent Application No. 60/969,230, filed Aug. 31, 2007, entitled “Resolution Enhancement Techniques For Interference-Assisted Lithography,” and U.S. Provisional Patent Application No. 60/969,280, filed Aug. 31, 2007, entitled “Integrated Interference-Assisted Lithography,” the entire disclosure of each of which is incorporated herein by reference for all purposes.

### BACKGROUND

Optical resolution for lithography is determined by Rayleigh's equation. For the state of the art ArF lithography systems with air between the final lens element and the focal plane (or, wafer surface), the optical resolution is limited to 63 nm half pitch (HP) with a numerical aperture (NA) of 0.93 and K₁ factor at 0.3.

Immersion lithography has also been proposed. Immersion lithography techniques replace the usual air gap between the final lens and a wafer surface with a liquid medium that has a refractive index greater than one. In such systems, the resolution may be reduced by a factor equal to the refractive index of the liquid by allowing lenses with higher numerical aperture (N.A.). Current immersion lithography tools use highly purified water for the immersion liquid, and can achieve feature sizes below the Rayleigh limit of non-immersion systems. Immersion lithography, however, suffers from various manufacturing issues not present in dry systems, such as new classes of defects: water marks, drying stains, water leaching, wafer edge peeling, and air bubbles that restrict full scale manufacturing efforts. Current development focuses on various manufacturing techniques that avoid these negative effects. The optical resolution for water-immersion lithography with an NA of 1.35 and K₁ factor of 0.3 is limited to 42 nm HP, per Rayleigh's equation. Further research is being conducted to seek lens materials, immersion fluids and photoresists with higher index of refraction to further reduce the resolution limit. However, few breakthroughs have been reported making high index of refraction immersion an unlikely candidate as the technology of choice for the next generation lithography.

Currently, there are a number of lithography techniques under development that seek to provide optical resolution below the Rayleigh limit. For example, some have suggested employing a double patterning technique. Such a system may employ two exposures on two photoresist layers and two developing steps. There are technical challenges to employing a double patterning technique; for instance, the required tolerance of alignment for the two patterns is much tighter than is possible with current state-of-the-art exposure tools (called scanners). Second, the two independent exposures lead to two independent parameter distributions which complicates device and design variability significantly. Moreover, the process of depositing and developing two photoresists, which may also require additional imaging layers such as antireflection coatings or hard masks, as well as requiring two exposures compared to the single exposure needed in single patterning approaches, increases the operation use and thus the cost of expensive scanners and thin-film processing tools.

Others have suggested using extreme ultraviolet (EUV) lithography as another solution to providing optical resolution below Rayleigh's limit for 193 nm optical lithography. Systems currently under development use 13.5 nm wavelength light sources. Various basic problems must be resolved before EUV lithography can be implemented in any manufacturing scenario, the most serious being low source power, contamination of the optics, the handling of masks and many general manufacturing issues. These challenges have limited EUV lithography as a viable manufacturing solution to optical resolutions below the Rayleigh limit of 193 nm systems.

Some double patterning techniques have been provided. Such double patterning techniques require 2 masks, 2 develops, and 2 resist coats. Each extra step further adds complexity, increases costs and can add potential for error.

Accordingly, there remains a general need in the art for an optical lithography system that can provide optical resolution near or below the Rayleigh limit.

### SUMMARY

A method for exposing a wafer is provided according to one embodiment. The method exposes a first plurality of substantially parallel lines on the wafer using interference lithography during a first exposure. The first exposure provides a first dosage to the first plurality of substantially parallel lines. The method further exposes second portions of the wafer using a second lithographic technique during a second exposure. The second exposure provides a second dosage to the second portions of the wafer. In some embodiments the second portions of the wafer overlap at least part of the first portions of the wafer, wherein those portions of the wafer that overlap with the first portion and the second portion are exposed with the first and the second dosage.

In some embodiments, the second lithographic technique may include electron beam lithography, EUV lithography, interference lithography, and/or optical photolithography. In some embodiments, the second lithography technique comprises optical photolithography that provides a mask with at least one assist feature.

In various embodiments, methods may optimize the first dosage based on the second dosage, optimize the exposure rate of the first exposure based on the exposure rate of the second exposure, optimize the second exposure based on the first dosage, and/or optimize the exposure rate of the second exposure based on the exposure rate of the first exposure.

In some embodiments, the method may provide a photoresist on the wafer and develop the photoresist following both the first exposure and the second exposure.

In some other embodiments, the method may provide a first photoresist on a hardmask layer of the wafer; develop the first photoresist following the first exposure and before the second exposure; etch the hardmask layer to transfer the pattern provided during the first exposure into the hardmask layer; provide a second photoresist on the wafer prior to the second exposure; develop the second photoresist following the second exposure; and etch the hardmask layer to transfer the pattern provided during the second exposure into the hardmask layer.

In some other embodiments, the method may provide a first photoresist on a hardmask layer of the wafer; develop the first photoresist following the first exposure and before the second exposure; freeze the first photoresist layer so that the first photoresist will not be sensitive to the second exposure; provide a second photoresist on the wafer prior to the second exposure; develop the second photoresist following the second exposure; and etch the hardmask layer to transfer the pattern provided during the first exposure and the second exposure into the hardmask layer.

According to one embodiment the method may provide a negative photoresist. The second portions may include at least one line that is substantially perpendicular to the plurality of substantially parallel lines such that at least after the developing the at least one line joins two of the plurality of substantially parallel lines. According to another embodiment, the method may provide a positive photoresist. The second portions include at least one line that is substantially perpendicular to the plurality of substantially parallel lines, such that at least after the developing the at least one line divides at least one of the plurality of substantially parallel lines. According to another embodiment, the method may provide a positive photoresist on the wafer. The second portions may include at least one line that substantially overlaps a portion of the plurality of substantially parallel lines, such that at least after the developing the at least one line bulges at least one of the plurality of substantially parallel lines.

According to another embodiment, a positive photoresist is provided on the wafer. The second portions include at least one line that substantially overlaps a portion of the plurality of substantially parallel lines, such that at least after the developing the at least one line trims at least one of the plurality of substantially parallel lines. According to another embodiment, a positive photoresist is provided on the wafer. The second portions include at least one line that is substantially perpendicular to a portion of the plurality of substantially parallel lines, such that at least after the developing the at least one line adds a tab to at least one of the plurality of substantially parallel lines.

A system for exposing a wafer is provided according to another embodiment. The system includes a two-beam interference lithography interferometer and a lithographic scanner. The two-beam interference lithography interferometer may be configured to expose the wafer using interference lithography during a first exposure that provides a plurality of substantially parallel lines of a first exposure dose on the wafer. The lithographic scanner may be configured to expose the wafer during a second exposure that provides a second exposure dose on portions of the wafer. In some embodiments, the second scanner comprises an optical photolithography scanner that includes a mask with at least one assist feature. In other embodiments, the second scanner comprises an optical photolithography scanner that is configured to underexpose at least a portion the wafer.

In some embodiments, the interferometer is configured to underexpose at least a portion of the wafer. The system may further comprises a chamber housing the interferometer and the lithographic scanner. In other embodiments, the system includes a first and a second chamber, such that the interferometer is house in one and the lithographic scanner is housed in the other.

A photolithography system is also provided, according to one embodiment, that includes interference lithography means; lithography means; and post processing means. The interference lithography means may provide a plurality of substantially parallel lines of a first exposure dose on the wafer. The lithography means may provide a second exposure dose on portions of the wafer. The post processing means aids in developing portions of the wafer.

A method for exposing a wafer is also provided according to one embodiment. The method includes providing a photoresist on a wafer. Then exposing the wafer with a first exposure according to a first exposure pattern using interference lithography. The first exposure pattern may include a plurality of substantially parallel lines. The first exposure pattern may also be configured to expose the wafer at the plurality of substantially parallel lines. The first exposure may also provide a first dosage to portions of the wafer. Portions of the wafer may also be exposed using an optical photolithography system that includes a mask. The exposure may provide a second dosage on portions of the wafer. The photoresist may then be developed after both the first exposure and the second exposure. In some embodiments, the order of the first and second exposure may be reversed.

A method for patterning a wafer is provided according to another embodiment. A first photoresist is provided on a wafer. The photoresist is exposed with a first exposure according to a first exposure pattern using four-beam interference lithography. The first exposure pattern may include a plurality of dots arrayed across the surface of the wafer. The exposure pattern may be configured to expose the photoresist at the plurality of dots. The first exposure may provide a first dosage to the photoresist. The photoresist may be exposed with a second exposure according to a second exposure pattern. The second exposure may provide a second dosage to the photoresist. In some embodiments, portions of the second exposure pattern overlap with portions of the first exposure pattern. In some embodiments, the second exposure exposes the wafer using electron beam lithography, optical photolithography, interference lithography, and/or extreme ultraviolet lithography. In some embodiments, the plurality of dots are arrayed in a plurality of substantially parallel lines in two substantially orthogonal directions.

In some embodiments, the photoresist includes a negative photoresist, and the method further comprises post processing the wafer to provide a plurality of undeveloped dots on the wafer. In some embodiments, the photoresist comprises a positive photoresist, and the method further comprises post processing the wafer to provide a plurality of developed holes in the wafer.

In some methods disclosed the first photoresist may be developed after exposing the photoresist with a first exposure and before exposing the photoresist with a second exposure; a second photoresist may be deposited on the wafer before exposing the photoresist with a second exposure; and the second photoresist may be developed after exposing the photoresist with a second exposure. In some embodiments of methods described herein, the first photoresist is developed after exposing the photoresist with a first exposure and after exposing the photoresist with a second exposure.

In some embodiments described herein, the wafer includes a hardmask layer; and the first photoresist is deposited on the hardmask layer. The first photoresist may be developed following the first exposure and before the second exposure. The first photoresist may be frozen such that the first photoresist is not be sensitive to the second exposure. The second photoresist may be deposited over a hardmask layer of the wafer prior to the second exposure. The second photoresist may be developed following the second exposure.

Another method for exposing a wafer is provided. According to some embodiments, the wafer is exposed with a first exposure according to a first exposure pattern using interference lithography and the wafer is exposed with a second exposure according to a second exposure pattern using four-beam interference lithography. In some embodiments, the first exposure pattern includes a plurality of substantially parallel lines, the exposure pattern is configured to expose the wafer at the plurality of substantially parallel lines, and/or the first exposure provides a first dosage to the wafer. In some embodiments, the second exposure pattern includes a plurality of dots arrayed across the surface of the wafer, the exposure pattern is configured to expose the wafer at the plurality of dots, and/or the second exposure provides a second dosage to the wafer. In some embodiments, the plurality of dots in the second exposure pattern substantially overlap the parallel lines in the first pattern.

In some embodiments described herein, a photoresist may be used with a dosage threshold that defines the dosage required for proper developing of the photoresist. In some embodiments, the first dosage is less than or equal to the dosage threshold, the second dosage is less than the dosage threshold, and/or the sum of the first dosage and the second dosage is greater than or equal to the dosage threshold. In some embodiments, a photoresist is used with a dosage threshold that defines the dosage required for proper developing of the photoresist. In some embodiments, the first dosage is greater than or equal to the dosage threshold, and the second dosage is less than the dosage threshold.

A photolithography system for exposing a wafer is provided according to another embodiment. The photolithography system includes a four-beam interference lithography interferometer and a lithographic scanner. In some embodiments, the four-beam interference lithography interferometer may be configured to expose the wafer with a first exposure according to a first exposure pattern that may include a plurality of substantially parallel lines. The exposure pattern may be configured to expose the wafer at the plurality of substantially parallel lines, and the first exposure provides a first dosage to the wafer. The lithographic scanner may be configured to expose the wafer with a second exposure according to a second exposure pattern that provides a second dosage to the wafer.

The lithographic scanner, in some embodiments, may include an optical photolithography scanner that includes a mask with at least one assist feature. In some embodiments, the lithographic scanner may include an optical photolithography scanner that is configured to underexpose at least a portion the wafer. In some embodiments, the interferometer may be configured to underexpose at least a portion the wafer during at least one of the first exposure and the second exposure. In some embodiments, a photolithography system may include a chamber, such that, both the four-beam interference lithography interferometer and the lithographic scanner are housed within the chamber. In some embodiments, a photolithography system may include a first chamber and a second chamber, such that, the four-beam interference lithography interferometer is housed within the first chamber, and the lithographic scanner is housed within the second chamber. In some embodiments, the lithographic scanner may be an optical photolithography scanner, an electron beam scanner, an extreme UV scanner, and/or an interference lithography scanner.

A method for patterning a wafer is provided according to another embodiment. The method may include means for depositing a photoresist on the wafer. Means for exposing the wafer with a first exposure according to a first exposure pattern using four-beam interference lithography may also be included. Such means may expose a pattern that includes a plurality of dots arrayed across the surface of the wafer. The exposure pattern may be configured to expose the wafer at the plurality of dots, and the first exposure may provide a first dosage to the wafer. Means for exposing the wafer with a second exposure according to a second exposure pattern that provides a second dosage to the wafer may also be provided. Means for means for developing the wafer to remove portions of the photoresist may also be provided.

A method for exposing is also provided. This method may include exposing the wafer with a first exposure according to a first exposure pattern using interference lithography and exposing the wafer with a second exposure according to a second exposure pattern using interference lithography. In some embodiments, the first exposure pattern includes a first plurality of substantially parallel lines, the exposure pattern is configured to expose the wafer at the plurality of substantially parallel lines, and/or the first exposure provides a first dosage to the wafer. In some embodiments, the second exposure pattern includes a second plurality of substantially parallel lines, the second plurality of parallel lines are substantially orthogonal from the first plurality of substantially parallel lines, the exposure pattern is configured to expose the wafer at the plurality of substantially parallel lines, and/or the second exposure provides a second dosage to the wafer.

A method for patterning a wafer is provided according to another embodiment. The method may include: depositing a hardmask layer on the wafer; depositing a first photoresist layer on the hardmask layer; exposing the first photoresist with a first exposure that includes a first pattern; developing the first photoresist; etching the underlying hardmask to transfer the first pattern to the hardmask layer; depositing a second photoresist layer on the hardmask layer; exposing the second photoresist with a second exposure that includes a second pattern; developing the second photoresist; and/or etching the underlying hardmask to transfer the second pattern to the hardmask layer.

### BRIEF DESCRIPTION OF THE DRAWINGS

A further understanding of the nature and advantages of the embodiments described herein may be realized by reference to the remaining portions of the specification and the drawings wherein like reference numerals are used throughout the several drawings to refer to similar components. In some instances, a sub-label is associated with a reference numeral and follows a hyphen to denote one of multiple similar components. When reference is made to a reference numeral without specification to an existing sub-label, it is intended to refer to all such multiple similar components.

FIG. 1A shows an image of various semiconductor features that may be achieved using some embodiments.

FIG. 1B shows a first latent exposure pattern produced using an interference lithography (IL) exposure according to one embodiment.

FIG. 1C shows a second latent exposure pattern produced using a second lithography technique according to one embodiment.

FIG. 1D shows the composite pattern on a substrate using the exposure shown in FIG. 1B and second exposure shown in FIG. 1C according to one embodiment.

FIG. 2A shows a first latent exposure pattern produced using, for example, an IL exposure according to one embodiment.

FIG. 2B shows a second latent exposure pattern produced using a second lithography technique in coordination with the IL line pattern shown in FIG. 2A according to one embodiment.

FIG. 2C shows the composite pattern on a substrate using the exposure shown in FIG. 2A and the second exposure shown in FIG. 2B creating a pattern of different hole sizes according to one embodiment.

FIG. 3A shows a first latent exposure pattern produced using, for example, an IL exposure according to one embodiment.

FIG. 3B shows a second latent exposure pattern produced using a second lithography technique in coordination with the IL line pattern shown in FIG. 3A according to one embodiment.

FIG. 3C shows the composite pattern on a substrate using the exposure shown in FIG. 3A and the second exposure shown in FIG. 3B according to one embodiment.

FIG. 4A shows a first latent exposure pattern produced using, for example, an IL exposure according to one embodiment.

FIG. 4B shows a second latent exposure pattern produced using a second lithography technique in coordination with the IL line pattern shown in FIG. 4A according to one embodiment.

FIG. 4C shows the composite pattern on a substrate using the exposure shown in FIG. 4A and the second exposure shown in FIG. 4B creating different line widths according to one embodiment.

FIG. 5A shows a first latent exposure pattern produced using, for example, an IL exposure according to one embodiment.

FIG. 5B shows a second latent exposure pattern produced using a second lithography technique in coordination with the IL line pattern shown in FIG. 5A according to one embodiment.

FIG. 5C shows the composite pattern on a substrate using the exposure shown in FIG. 5A and the second exposure shown in FIG. 5B creating a pad landing on a line according to one embodiment.

FIG. 5D shows a first latent exposure pattern produced using, for example, an IL exposure according to one embodiment.

FIG. 5E shows a second latent exposure pattern produced using a second lithography technique in coordination with the IL line pattern shown in FIG. 5A according to one embodiment.

FIG. 5F shows the composite pattern on a substrate using the exposure shown in FIG. 5A and the second exposure shown in FIG. 5B creating a pad landing on a line according to one embodiment.

FIG. 6A shows a first latent exposure pattern produced using, for example, an IL exposure according to one embodiment.

FIG. 6B shows a second latent exposure pattern produced using a second lithography technique in coordination with the IL line pattern shown in FIG. 6A according to one embodiment.

FIG. 6C shows the composite pattern on a substrate using the exposure shown in FIG. 6A and the second exposure shown in FIG. 6B creating lines of the same width with different pitches according to one embodiment.

FIG. 7A shows a first latent exposure pattern produced using, for example, an IL exposure according to one embodiment.

FIG. 7B shows a second latent exposure pattern produced using a second lithography technique in coordination with the IL line pattern shown in FIG. 7A according to one embodiment.

FIG. 7C shows the composite pattern on a substrate using the exposure shown in FIG. 7A and the second exposure shown in FIG. 7B creating a hole pattern according to one embodiment.

FIG. 8A shows a first latent exposure pattern produced using, for example, an IL exposure on a positive photoresist according to one embodiment.

FIG. 8B shows a second latent exposure pattern produced using a second lithography technique in coordination with the IL line pattern shown in FIG. 8A according to one embodiment.

FIG. 8C shows the composite pattern on a substrate with a positive photoresist using the IL line pattern shown in FIG. 8A and the second exposure shown in FIG. 8B creating lines with breaks according to one embodiment.

FIG. 9A shows a first latent exposure pattern produced using IL on a negative photo resist according to one embodiment.

FIG. 9B shows a second latent exposure pattern produced using a second lithography technique in coordination with the IL line pattern shown in FIG. 9A according to one embodiment.

FIG. 9C shows the composite pattern on a substrate with a negative photoresist using the IL line pattern shown in FIG. 9A and the second exposure shown in FIG. 9B according to one embodiment.

FIG. 10A shows a first latent exposure pattern produced using IL with a positive photoresist according to one embodiment.

FIG. 10B shows a second latent exposure pattern produced using a second lithography technique in coordination with the IL line pattern shown in FIG. 10A according to one embodiment.

FIG. 10C shows the resulting hole pattern on a substrate with a positive photoresist using the IL line pattern shown in FIG. 10A and the second exposure shown in FIG. 10B according to one embodiment.

FIG. 10D shows a first latent exposure pattern produced using IL on a negative photoresist according to one embodiment.

FIG. 10E shows a second latent exposure pattern produced using a second lithography technique in coordination with the IL line pattern shown in FIG. 10D according to one embodiment.

FIG. 10F shows the resulting hole pattern on a substrate with a negative photoresist using the IL line pattern shown in FIG. 10D and second exposure shown in FIG. 10E according to one embodiment.

FIG. 11A shows a first latent exposure pattern produced using IL with a positive non-linear photoresist according to one embodiment.

FIG. 11B shows a second latent exposure pattern produced using a second lithography technique in coordination with the IL line pattern shown in FIG. 11A according to one embodiment.

FIG. 11C shows the resulting hole pattern on a substrate with a positive non-linear photoresist using the IL line pattern shown in FIG. 11A and the second exposure shown in FIG. 11B according to one embodiment.

FIG. 11D shows a first latent exposure pattern produced using IL on a negative non-linear photoresist according to one embodiment.

FIG. 11E shows a second latent exposure pattern produced using a second lithography technique in coordination with the IL line pattern shown in FIG. 11D according to one embodiment.

FIG. 11F shows the resulting hole pattern on a substrate with a negative non-linear photoresist using the IL line pattern shown in FIG. 11D and second exposure shown in FIG. 11E according to one embodiment.

FIG. 12A shows a first latent exposure pattern produced using IL on a positive photoresist according to one embodiment.

FIG. 12B shows a second latent exposure pattern produced using a second lithography technique that includes assist features in coordination with the IL line pattern shown in FIG. 12A according to one embodiment.

FIG. 12C shows the composite pattern on a substrate according to one embodiment.

FIG. 13A shows a first latent exposure pattern produced using, for example, an IL exposure according to one embodiment.

FIG. 13B shows a second latent exposure pattern produced using a second lithography technique that includes assist features in coordination with the IL line pattern shown in FIG. 13A according to one embodiment.

FIG. 13C shows the composite pattern with two line breaks on a substrate using the exposure shown in FIG. 13A and the second exposure shown in FIG. 13B according to one embodiment.

FIG. 14A shows a first latent exposure pattern produced using, for example, an IL exposure according to one embodiment.

FIG. 14B shows a second latent exposure pattern produced using a second lithography technique that includes assist features in coordination with the IL line pattern shown in FIG. 14A according to one embodiment.

FIG. 14C shows the composite pattern with a single line break on a substrate using the exposure shown in FIG. 14A and the second exposure shown in FIG. 14B according to one embodiment.

FIG. 15A shows a first latent exposure pattern produced using, for example, an IL exposure according to one embodiment.

FIG. 15B shows an OPL phase shift mask (PSM) with assist features used to expose a substrate in coordination with the IL line pattern shown in FIG. 15A according to one embodiment.

FIG. 15C shows the composite pattern on a substrate using the exposure shown in FIG. 15A and the second exposure shown in FIG. 15B according to one embodiment.

FIG. 16 shows a flowchart of a method using interference-assisted lithography (IAL) techniques with an IL exposure and an OPL exposure according to one embodiment.

FIG. 17 shows a flowchart of a method using interference-assisted lithography (IAL) techniques with an OPL exposure and an IL exposure according to one embodiment.

FIG. 18 shows a flowchart of a method using interference-assisted lithography (IAL) techniques with an EUV-IL exposure and an OPL exposure according to one embodiment.

FIG. 19 shows a flowchart of a method using interference-assisted lithography (IAL) techniques with an e-beam lithography exposure and an IL exposure according to one embodiment.

FIG. 20 shows a flowchart of a method using interference-assisted lithography (IAL) techniques with an OPL with extreme dipole exposure to emulate interference and an OPL trim exposure according to one embodiment.

FIG. 21 shows a flowchart of a method using interference-assisted lithography (IAL) techniques with an IL exposure, an OPL exposure and an e-beam lithography exposure according to one embodiment.

FIG. 22 shows a flowchart of a method using interference-assisted lithography (IAL) techniques with an OPL with extreme dipole exposure and an e-beam lithography exposure according to one embodiment.

FIG. 23 shows a flowchart of a method using interference-assisted lithography (IAL) techniques with a two-beam IL exposure and a four-beam IL exposure according to one embodiment.

FIG. 24 shows a flowchart of a method using interference-assisted lithography (IAL) techniques with a two-beam IL exposure, a three-beam IL exposure and a four-beam IL exposure according to one embodiment.

FIG. 25 shows a flowchart of a method using interference-assisted lithography (IAL) techniques with a four-beam IL exposure and a two-beam IL exposure according to one embodiment.

FIG. 26 shows a flowchart of a method using interference-assisted lithography (IAL) techniques with a two-beam IL exposure and an orthogonal two-beam IL exposure according to one embodiment.

FIG. 27 shows a flowchart of a method using interference-assisted lithography (IAL) techniques with a two-beam IL exposure, an orthogonal two-beam exposure and an OPL exposure according to one embodiment.

FIG. 28 shows a flowchart of a method using interference-assisted lithography (IAL) techniques with a two-beam IL exposure, an orthogonal two-beam exposure and an e-beam lithography exposure according to one embodiment.

FIG. 29 shows a flowchart of a method using interference-assisted lithography (IAL) techniques with a two-beam IL exposure, an orthogonal two-beam exposure and an EUV-IL exposure according to one embodiment.

FIG. 30 shows a flowchart of a method using interference-assisted lithography (IAL) techniques with an OPL exposure, a two-beam IL exposure and an orthogonal two-beam exposure according to one embodiment.

FIG. 31A shows a first latent exposure pattern produced using IL with a positive photoresist according to one embodiment.

FIG. 31B shows a second latent exposure pattern that includes two triangles used to expose a substrate in coordination with the IL line pattern shown in FIG. 31A according to one embodiment.

FIG. 31C shows the resulting hole pattern on a substrate with a positive photoresist using the IL line pattern shown in FIG. 31A and the second exposure shown in FIG. 10B according to one embodiment.

FIG. 32A shows a first latent exposure pattern produced using IL with a positive photoresist according to one embodiment.

FIG. 32B shows a second latent exposure pattern that includes two L-shaped figures used to expose a substrate in coordination with the IL line pattern shown in FIG. 32A according to one embodiment.

FIG. 32C shows the resulting hole pattern on a substrate with a positive photoresist using the IL line pattern shown in FIG. 32A and the second exposure shown in FIG. 32B according to one embodiment.

FIG. 33A shows a first latent exposure pattern produced using IL with a positive photoresist according to one embodiment.

FIG. 33B shows a second latent exposure pattern that includes two cross shapes used to expose a substrate in coordination with the IL line pattern shown in FIG. 33A according to one embodiment.

FIG. 33C shows the resulting hole pattern on a substrate with a positive photoresist using the IL line pattern shown in FIG. 33A and the second exposure shown in FIG. 33B according to one embodiment.

FIG. 34A shows a first latent exposure pattern produced using IL with a positive photoresist according to one embodiment.

FIG. 34B shows a second latent exposure pattern that includes two X-shapes used to expose a substrate in coordination with the IL line pattern shown in FIG. 34A according to one embodiment.

FIG. 34C shows the resulting hole pattern on a substrate with a positive photoresist using the IL line pattern shown in FIG. 34A and the second exposure shown in FIG. 34B according to one embodiment.

FIG. 35A shows a first latent exposure pattern produced using IL with a positive photoresist according to one embodiment.

FIG. 35B shows a second latent exposure pattern that includes a series of lines used to expose a substrate in coordination with the IL line pattern shown in FIG. 35A according to one embodiment.

FIG. 35C shows the resulting hole pattern on a substrate with a positive photoresist using the IL line pattern shown in FIG. 35A and the second exposure shown in FIG. 35B according to one embodiment.

FIG. 36A shows a first latent exposure pattern produced using IL with a positive photoresist according to one embodiment.

FIG. 36B shows a second latent exposure pattern that includes a series of different shapes used to expose a substrate in coordination with the IL line pattern shown in FIG. 36A according to one embodiment.

FIG. 36C shows the resulting hole pattern on a substrate with a positive photoresist using the IL line pattern shown in FIG. 36A and the second exposure shown in FIG. 36B according to one embodiment.

FIG. 37A shows a first latent exposure pattern produced using, for example, an IL exposure according to one embodiment.

FIG. 37B shows a second latent exposure pattern produced using a second lithography technique that includes assist features in coordination with the IL line pattern shown in FIG. 37A according to one embodiment.

FIG. 37C shows the composite pattern with bulges in the lines on a substrate using the exposure shown in FIG. 37A and the second exposure shown in FIG. 37B according to one embodiment.

FIG. 38A shows a first latent exposure pattern of a horizontal line pattern on the left-most third of a substrate produced using, for example, a first IL exposure according to one embodiment.

FIG. 38B shows the resulting pattern on the substrate using the IL exposure shown in FIG. 38A according to one embodiment.

FIG. 38C shows a latent exposure pattern of a horizontal line pattern on the middle third of a substrate produced using, for example, a first IL exposure according to one embodiment.

FIG. 38D shows the resulting pattern on the substrate using the IL exposures shown in FIGS. 38A and 38C according to one embodiment.

FIG. 38E shows a latent exposure pattern of a vertical line pattern on the middle third of a substrate produced using, for example, a third IL exposure according to one embodiment.

FIG. 38F shows the resulting pattern on the substrate using the IL exposures shown in FIGS. 38A, 38C and 38E according to one embodiment.

FIG. 38G shows a latent exposure pattern of a horizontal line pattern on the right-most third of a substrate produced using, for example, a fourth IL exposure according to one embodiment.

FIG. 38H shows the resulting pattern on the substrate using the IL exposures shown in FIGS. 38A, 38C, 38E and 38G according to one embodiment.

FIG. 39A shows an image of various semiconductor features that may be achieved using some embodiments.

FIG. 39B shows a latent exposure pattern produced using an IL exposure according to one embodiment.

FIG. 39C shows a second latent exposure pattern used to expose a substrate in coordination with the IL line pattern shown in FIG. 39B according to one embodiment.

FIG. 39D shows the composite pattern of an active layer with bulges on a substrate using the exposure shown in FIG. 39B and second exposure shown in FIG. 39C according to one embodiment.

FIG. 40A shows an image of various semiconductor features that may be achieved using some embodiments.

FIG. 40B shows a latent exposure pattern produced using an IL exposure according to one embodiment.

FIG. 40C shows a second latent exposure pattern used to expose a substrate in coordination with the IL line pattern shown in FIG. 40B according to one embodiment.

FIG. 40D shows the composite pattern corresponding to the gate layer shown in FIG. 40A using the exposure shown in FIG. 40B and second exposure shown in FIG. 40C according to one embodiment.

FIG. 41 shows a block diagram of an interference lithography system according to one embodiment.

FIG. 42 shows a diagram of an electron beam apparatus according to one embodiment.

FIG. 43 shows a flowchart of a double exposure process using the two depositions shown in FIG. 16.

FIG. 44 shows a flowchart of a double patterning process using the two depositions shown in FIG. 16.

FIG. 45 shows a flowchart of a litho-freeze process using the two depositions shown in FIG. 16.

### DETAILED DESCRIPTION

Embodiments described herein provide for a multi-exposure lithography system. According to some embodiments, the system exposes a target using at least two of the following lithography tools: two-beam interference lithography (IL), three-beam IL, four-beam IL, optical photolithography (OPL), e-beam lithography, OPL with extreme dipole, or extreme ultraviolet interference lithography (EUV-IL). Any other lithography tool may also be used to expose the target. In some embodiments, two, three, four, five or more exposures may be used. Either or both of the exposures may underexpose portions of the target in order to compensate for the additional dose from another exposure. Modified resolution enhancement techniques (RET) may be used in one or more of the exposures to enhance the combined exposure. Methods for exposing a target using multiple exposures are also provided.

The target may include a substrate and/or a wafer that may include a layer of positive and/or a negative photoresist. In some embodiments, the photoresist may be non-linear, such that, the photoresist is active only after a certain dosage is reached. Some embodiments include a substrate and/or wafer with a combined positive and negative photoresist. The positive-negative photoresist may be applied in a single resist application, in a two-step application and/or in a multi-step application. The positive-negative photoresist may also be created by applying either a positive and/or negative photoresist and then treating the photoresist to change the tone of the photoresist in specific areas. Accordingly, the photoresist may be a combined positive-negative photoresist. When the disclosure refers exposing a wafer, in some cases it can be assumed that the wafer includes a photoresist.

Some embodiments may apply 32 nm half pitch (HP) or smaller patterns on a wafer. Various embodiments may also provide at least 22 nm or 16 nm HP patterns.

In some embodiments, two exposures are used. In these embodiments the exposure and/or dosage may vary between the first and second exposure. For example, if the first exposure may be underexposed then the second exposure may provide an increased exposure to compensate for the underexposure. The exposure and/or dosage may also depend on the photoresist used. Moreover, the second or first exposure may be provided to compensate for underexposures during the other exposure step. In a one embodiment, an OPL exposure occurs first followed by an IL exposure.

In various embodiments, exposures may use various light sources during the exposures. Such light sources may include lasers. For example, an excimer laser may include an Ar₂ laser producing light with a wavelength of 126 nm, a Kr₂ laser producing light with a wavelength of 146 nm, an F₂ laser producing light with a wavelength of 157 nm, an Xe₂ laser producing light with a wavelength of 172 or 175 nm, an ArF laser producing light with a wavelength of 193 nm, a KrF laser producing light with a wavelength of 248 nm, an XeBr laser producing light with a wavelength of 282 nm, an XeCl laser producing light with a wavelength of 308 nm, an XeF laser producing light with a wavelength of 351 nm, a KrCl laser producing light with a wavelength of 222 nm, a Cl₂ laser producing light with a wavelength of 259 nm, or a N₂ laser producing light with a wavelength of 337 nm. Various other lasers operating in other spectral bands may also be used without deviating from the scope of the embodiments described herein. The various embodiments will be described using an ArF excimer laser that produces light at 193 nm. In yet another embodiment, an extreme ultraviolet (EUV) light source may be used. For example, the EUV light source may produce light with a wavelength of 13.6 nm.

Various immersion techniques may also be used in either or both exposures. For example, water or other high index materials may be used. In some embodiments, alignment techniques may be used to align the substrate between exposures.

Some embodiments may expose a photoresist with various photolithography techniques. Photoresists can be classified into two groups, positive resists and negative resists. A positive resist is a type of photoresist in which the portion of the photoresist that is exposed to light becomes soluble to the photoresist developer and the portion of the photoresist that is unexposed remains insoluble to the photoresist developer. A negative resist is a type of photoresist in which the portion of the photoresist that is exposed to light becomes relatively insoluble to the photoresist developer. The unexposed portion of the photoresist is dissolved by the photoresist developer.

The following figures are not drawn to scale. The line widths and pitches shown are not meant to show proportionality. Instead, the figures are used to represent how multiple exposures using various techniques may provide various features and benefits including decreased line widths and/or pitches, various dot and/or hole patterns, as well as provide numerous other features.

Many of the following figures show latent exposure patterns created using various photolithography techniques. In some cases two figures are provided that show latent exposure patterns that if combined produce a line pattern on a photoresist. It should be noted that any of the latent exposure patterns may be created using any lithography technique. Moreover, in various embodiments, some latent exposure patterns may underexpose the photoresist. When combined with another exposure the overlap of underexposed portions may provide sufficient dosage to allow for proper development. Therefore, while one lithography technique may be specified in the following disclosure, another lithography technique may be used.

Moreover, in some embodiments, when a wafer with a photoresist is exposed in a first exposure chamber and is moved to a second exposure chamber, the wafer may require alignment within the chamber prior to exposure.

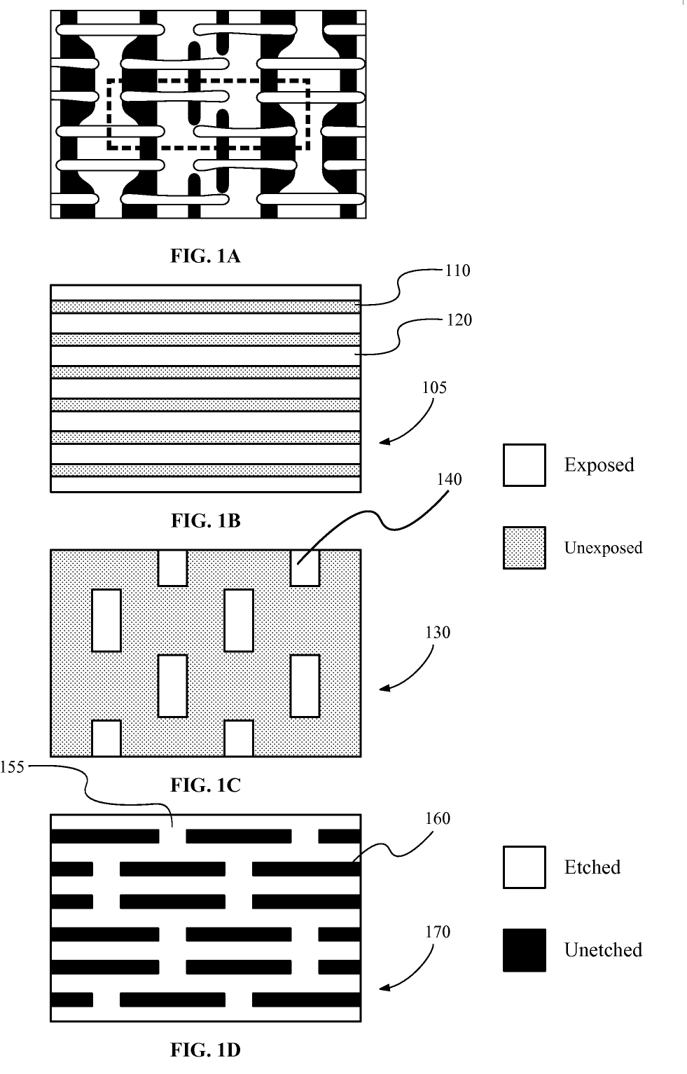

FIG. 1A shows an image of an SRAM cell with multiple layers. The line patterns of any of the layers of the SRAM cell may be created using various embodiments described herein. For example, the line pattern may be achieved as further shown in FIGS. 1B-1C. FIG. 1B shows a latent exposure pattern on a positive photoresist using, for example, interference lithography (IL). The white spaces 120 are exposed portions of the photoresist and the shaded spaces 110 are portions of the photoresist that are not exposed in the first exposure. Various other lithography techniques may also be used to produce the line pattern shown in the figure. FIG. 1C shows a latent exposure pattern 130 created from a second lithographic exposure. Again, the white portions 140 show the areas exposed on the photoresist and the shaded portions are left unexposed. For example, this pattern may be created using optical photolithography (OPL), EUV, or e-beam lithography. Using OPL, a mask similar to the latent exposure pattern 130 may be used. The mask may permit and/or restrict light from exposing the photoresist.

FIG. 1D shows the resulting composite pattern 170 of the line pattern after exposing the wafer with the two exposures shown in FIGS. 1B-1C. During post-exposure processing, such as developing, etching, baking, and/or annealing, the exposed portions 155 of the photoresist are developed and are shown in white, while the unexposed portions 160 are not developed and are shown in black. The second exposure shown in FIG. 1C produces breaks in the unexposed lines 120 shown in FIG. 1A. The resulting image is similar, for example, to the gate layer (also referred to as the poly layer or poly-gate layer) shown in FIG. 1A. In some embodiments, the second exposure may actually occur prior to the IL exposure.

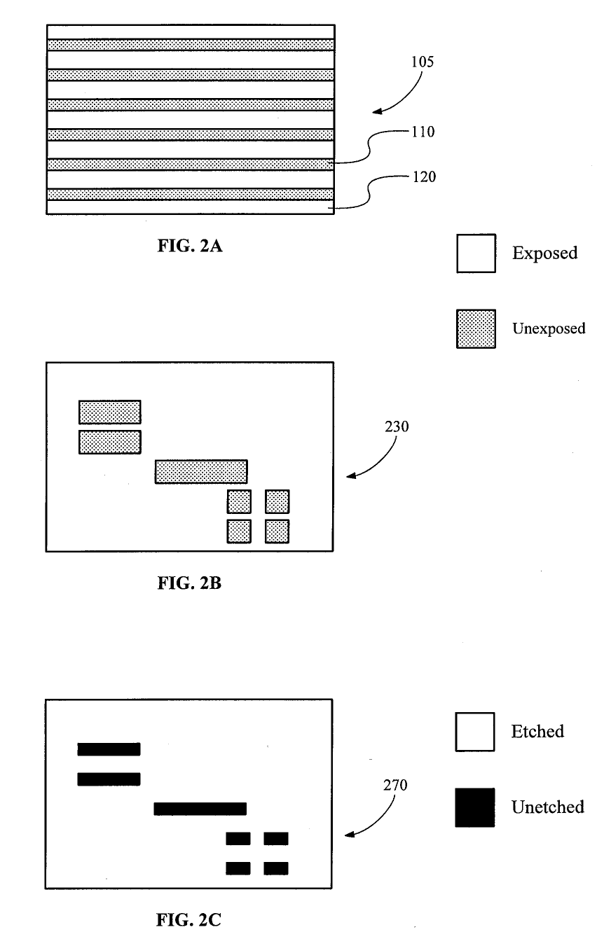

FIGS. 2A-2C show another example of a two-exposure process according to another embodiment. A latent exposure pattern on a positive photoresist using, for example, interference lithography (IL) is shown in FIG. 2A. The latent exposure pattern is provided on a positive photoresist. The white spaces 120 are exposed portions and the shaded spaces 110 are unexposed portions of the photoresist. FIG. 2B shows a latent exposure pattern 230 of a second lithographic exposure. For example, this pattern may be created using OPL, EUV, or electron beam lithography. A mask may be used, for example, when using OPL that has a pattern similar to the one shown in the latent exposure pattern 130. FIG. 2C shows the composite pattern 270 resulting from the two exposures shown in FIGS. 2A-2B. The resulting composite pattern 270 provides a unique contact pad pattern as shown in FIG. 2C. During post-exposure processing, such as developing and/or etching, the exposed portions of the photoresist are developed and are shown in white, while the unexposed portions are not developed and/or etched and are shown in black.

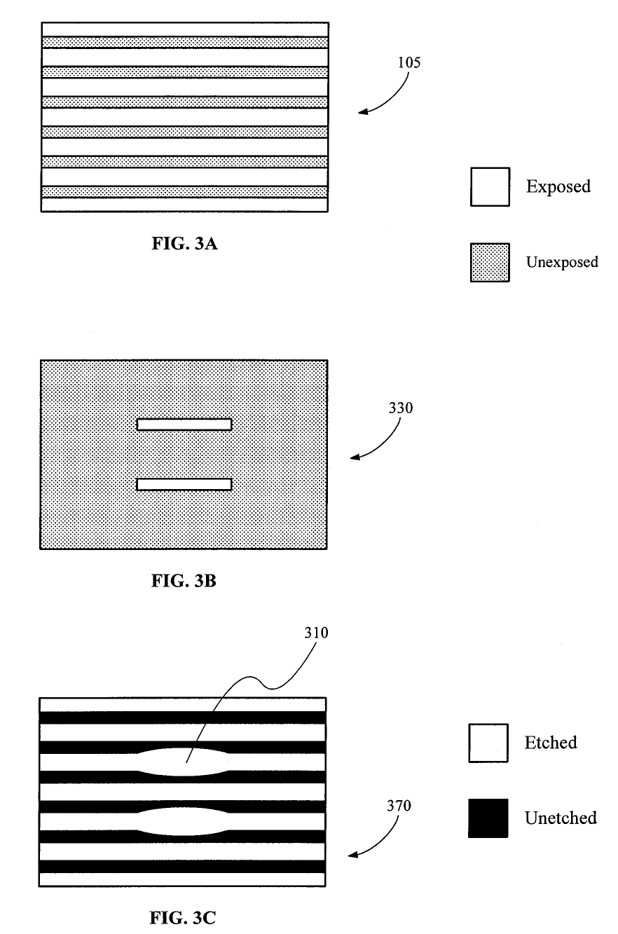

FIGS. 3A-3C depict steps for providing SRAM active area (AA) patterns on a substrate according to another embodiment. A latent exposure pattern is provided on a positive photoresist using, for example, IL as shown in FIG. 3A. A latent exposure pattern 330 of a second lithographic exposure is shown in FIG. 3B. FIG. 3C shows the composite pattern 370 created using the combined exposures from FIGS. 3A-3B. The composite pattern shows the ability to obtain a local variation of the pattern width (useful for active areas) without impacting the long range periodicity of the overall pattern; in some embodiments this can be useful for active areas. During post-exposure processing, such as developing, the exposed portions of the photoresist are developed, as shown in white, leaving the undeveloped portions, shown in black. Active areas 310 are shown on the composite pattern. The process described in relation to FIGS. 3A-3C may be used, for example, to create an active areas, gate trim and/or landing pads.

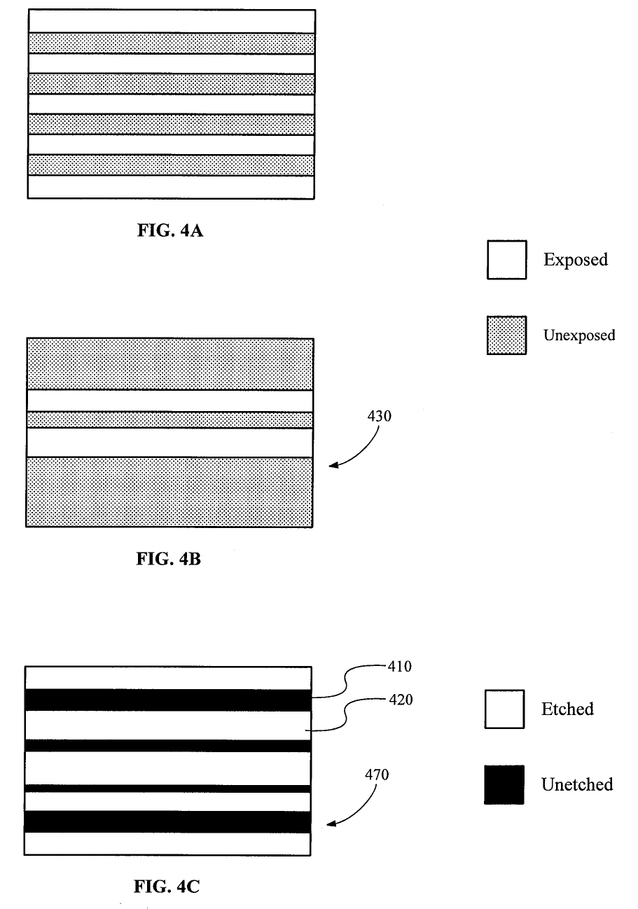

FIGS. 4A-4C depict steps for providing a pattern with lines of differing widths according to one embodiment. A latent exposure pattern on a positive photoresist using, for example, IL is shown in FIG. 4A. The latent exposure pattern is provided on a positive photoresist. A latent exposure pattern 430 of a second lithographic exposure is shown in FIG. 4B. FIG. 4C shows the composite pattern 470 created using the combined exposures from FIGS. 4A-4B. For example, the composite pattern shows the ability to obtain different line widths without impacting the pitch of the overall periodic pattern. During post-exposure processing, such as developing, the exposed portions of the photoresist are developed leaving the undeveloped portions, in black. This composite pattern includes lines 410 with differing widths and differing pitches 420. The process described in relation to FIGS. 4A-4C may be used, for example, to create interconnects.

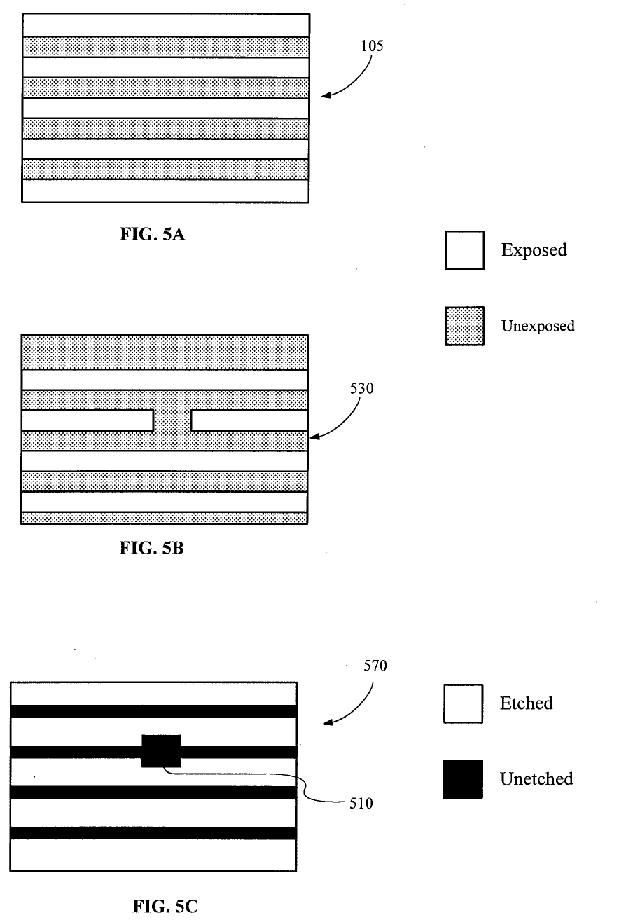

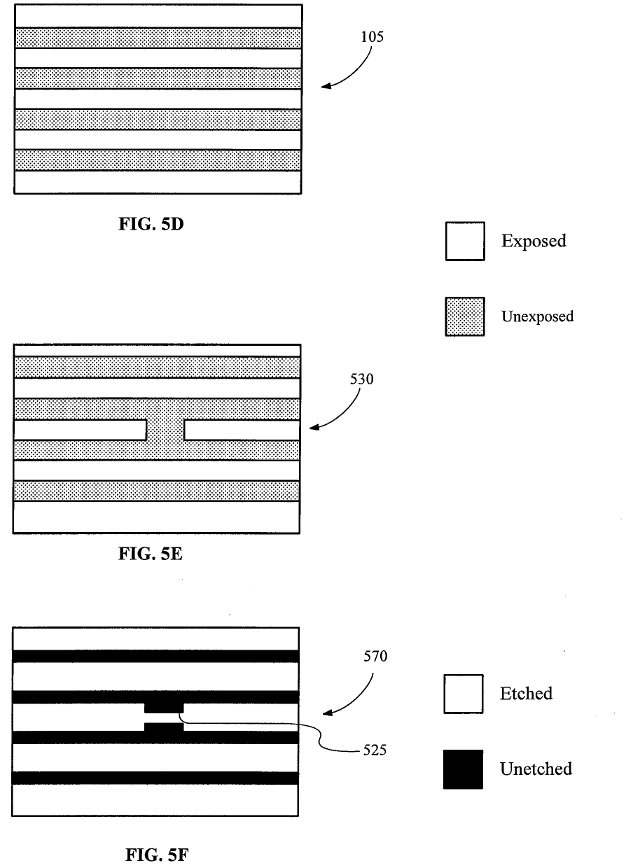

FIGS. 5A-5C depict steps for providing a pattern with two contact tabs on a single line according to one embodiment. A latent exposure pattern on a positive photoresist using, for example, IL is shown in FIG. 5A. The latent exposure pattern is provided on a positive photoresist. A latent exposure pattern 530 of a second lithographic exposure is shown in FIG. 5B. FIG. 5C shows the composite pattern 570 created using the combined exposures from FIGS. 5A-5B. During post-exposure processing, such as resist development or developing, the exposed portions of the photoresist are developed, as shown in white, leaving the unexposed portions shown in black. The composite pattern 570 includes a contact tab 510 that extends both directions on the unetched line. The process described in relation to FIGS. 5A-5C may be used, for example, to create landing pads.

FIGS. 5D-5F depict steps for providing a pattern with contact tab on two distinct adjacent lines according to one embodiment. A latent exposure pattern is provided on a positive photoresist using, for example, IL as shown in FIG. 5A. A latent exposure pattern 530 of a second lithographic exposure is shown in FIG. 5E. FIG. 5F shows the composite pattern 570 created using the combined exposures from FIGS. 5D-5E. During post-exposure processing, such as resist development or developing, the exposed portions of the photoresist are developed, as shown in white, leaving the unexposed portions shown in black. The composite pattern 570 includes a contact tab 525 on two adjacent unetched lines. The process described in relation to FIGS. 5D-5F may be used, for example, to create landing pads.

In some embodiments a nonlinear photoresist may be used with an exposure threshold required in order to develop the resist. The second exposure adds additional dosage to some exposed portions of the target. The IL exposure may underexpose portions of the photoresist, while the second exposure may further provide the dosage required to overcome the dosage threshold of the target and/or substrate. Thus, during the second exposure, the center portion of the latent exposure pattern does not expose the target and this portion of the target is not developed and/or etched leaving, for example, the contact tab shown in FIG. 5C. Moreover, the second exposure may provide additional exposure to the exposure lines in the first exposure. The composite pattern shows the ability to obtain local extensions of lines (such as contact or via landing pads) without impacting the pitch of the overall periodic pattern.

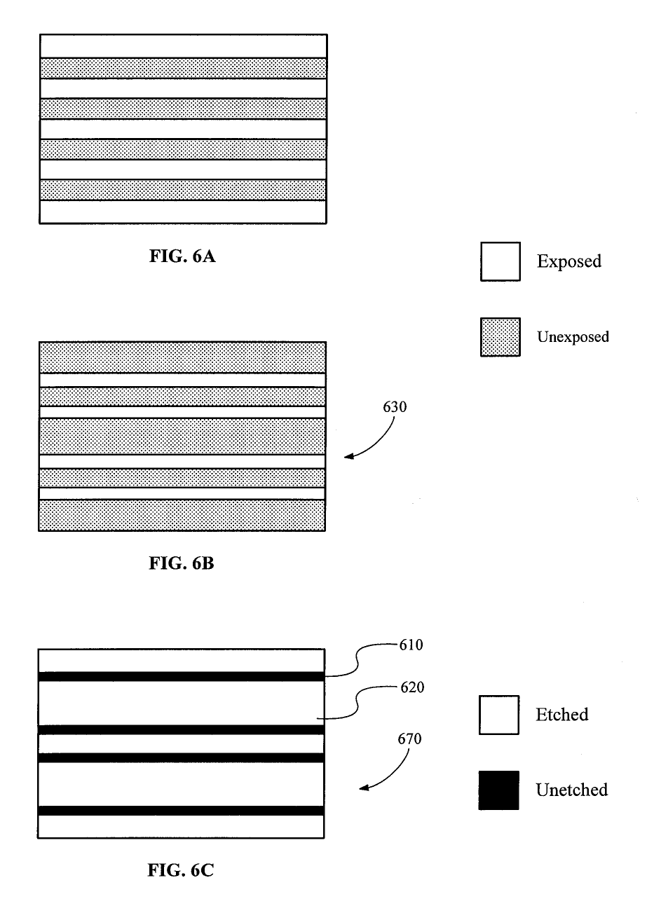

FIGS. 6A-6C depict steps for providing a pattern with lines of the same width but varying pitches according to another embodiment. A latent exposure pattern is provided on a positive photoresist using, for example, IL as shown in FIG. 6A. A latent exposure pattern 630 of a second lithographic exposure is shown in FIG. 6B. FIG. 6C shows the composite pattern 670 created using the combined exposures from FIGS. 6A-6B. The composite pattern 670 includes pitches 620 of varying widths and includes lines 610 with the same widths. The second exposure exposes portions of the photoresist that were unexposed in the first exposure and thus removes selected lines from the original, periodic pattern. The process described in relation to FIGS. 6A-6C may be used, for example, to create interconnects.

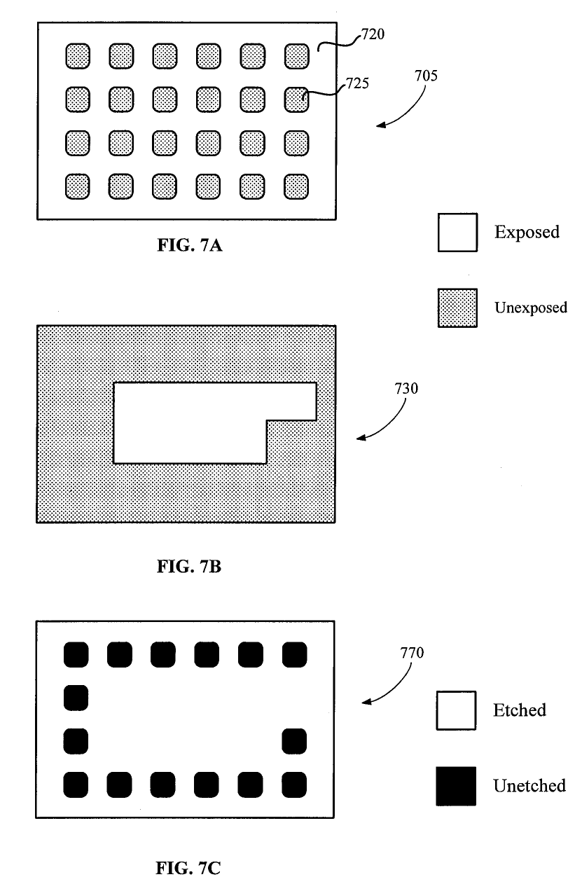

FIG. 7A shows a latent exposure dot pattern 705 produced using, for example, an IL exposure on a positive resist. The white portions 720 are exposed and the shaded portions 725 are unexposed. The pattern 705 may be created, for example, using a four-beam IL exposure or with successive orthogonal two-beam IL exposures. FIG. 7B shows a second latent exposure pattern 730 produced during at least a second lithographic exposure. FIG. 7C shows the composite pattern 770 created using the IL exposure shown in FIG. 7A and the second exposure shown in FIG. 7B. During post-exposure processing, such as resist development or developing, the unexposed pattern of dots of the target are not developed and/or etched away, shown in black, leaving the exposed portions that are developed away, shown in white.

Various other unique patterns may be created using various lithography techniques such as the use of masks with OPL. The above description and FIGS. 7A-7C show and/or describe one type of composite dot pattern. Using an IL exposure and a second exposure, nearly any type of pattern may be created from a single dot to multiple dot patterns. These patterns may be used to create contacts, vias, pads, through-the-wafer holes, and holes for other applications, such as, for example, shallow trench isolation and/or deep trench capacitors, etc.

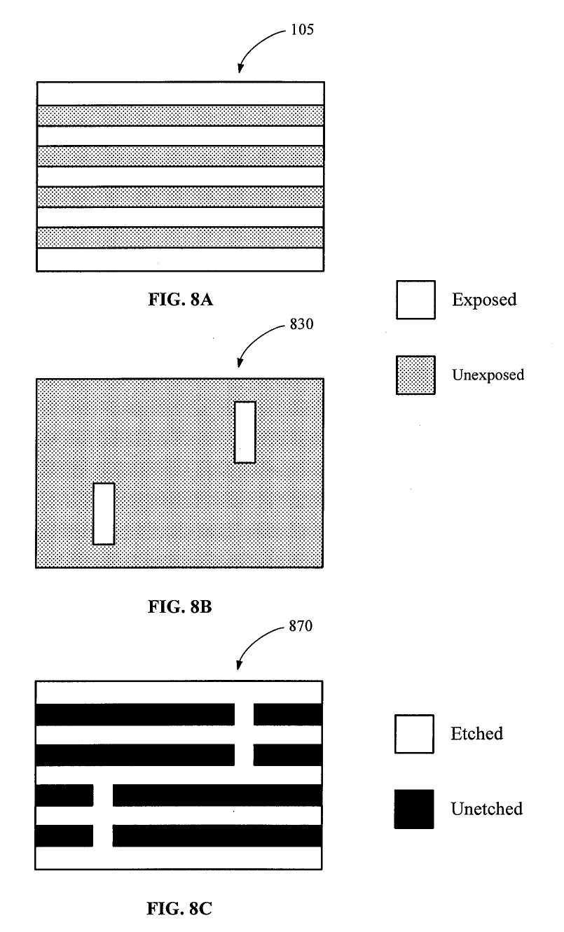

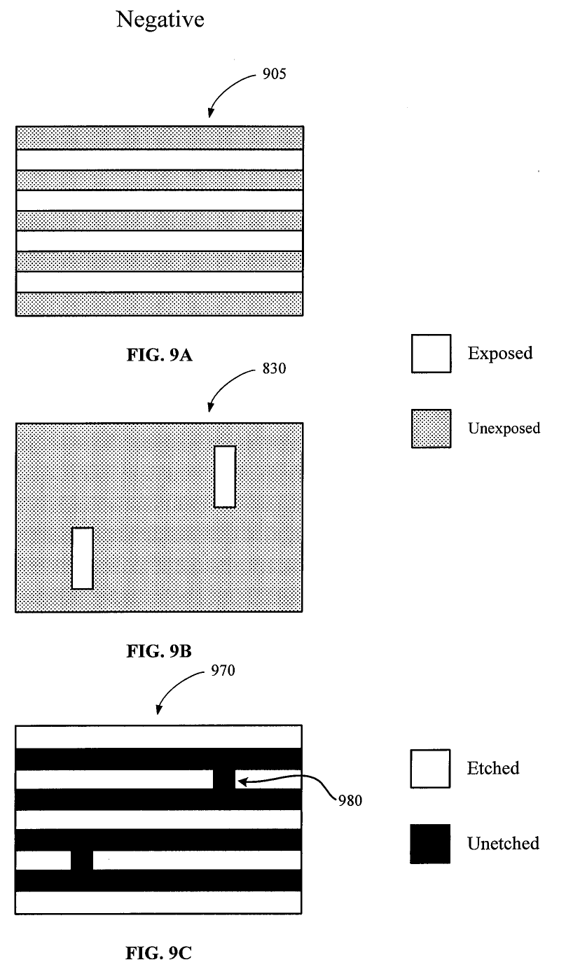

FIGS. 8A-8C and 9A-9C show the different results from using second exposure patterns on both positive and negative photoresists according to various embodiments. Starting with FIG. 8A, a latent exposure line pattern 105 is produced on a positive photoresist using, for example, an IL exposure. A transposed IL set up will provide a similar latent exposure pattern 905 on a negative photoresist as shown in FIG. 9A. The white portions are the exposed portions of the photoresists and the shaded portions are the unexposed portions of the photoresist. Similar second latent exposure patterns 830 are provided during a second exposure in both cases in FIGS. 8B and 9B. FIGS. 8C and 9C show the resulting patterns 870, 970 after post-exposure processing. After post-exposure processing the positive photoresist cuts the lines shown in FIG. 8A resulting in the pattern shown in the post-exposure processing 870 in FIG. 8C. On the other hand, after post-exposure processing, the negative photoresist exposes the white portions of the IL pattern 905 and provides further latent exposure patterns 830 as shown in the composite image 980 in FIG. 9C. The process described in relation to FIGS. 8A-8C and 9A-9C may be used, for example, to create interconnects and/or portions of the gate layer.

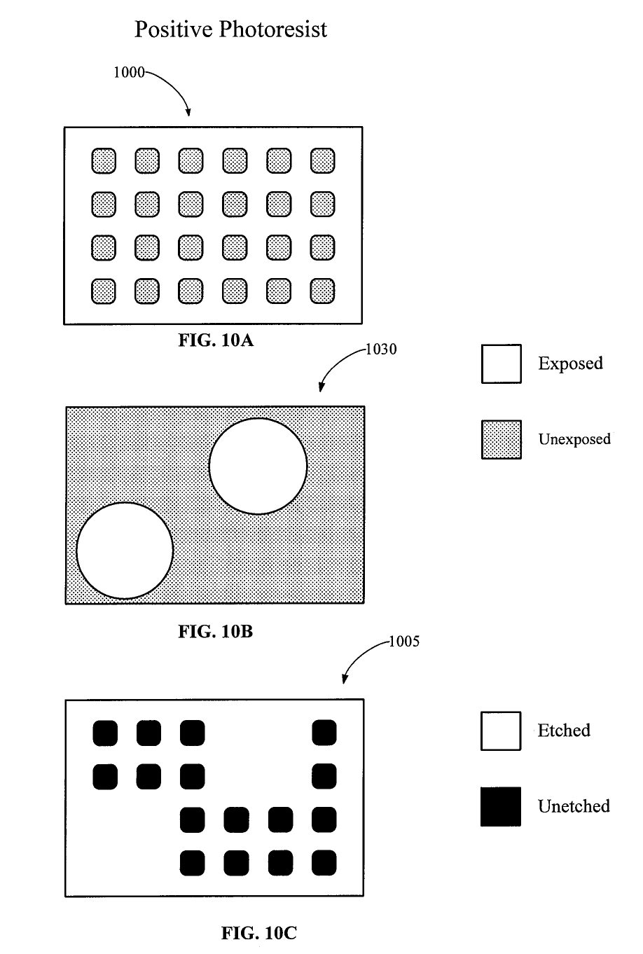

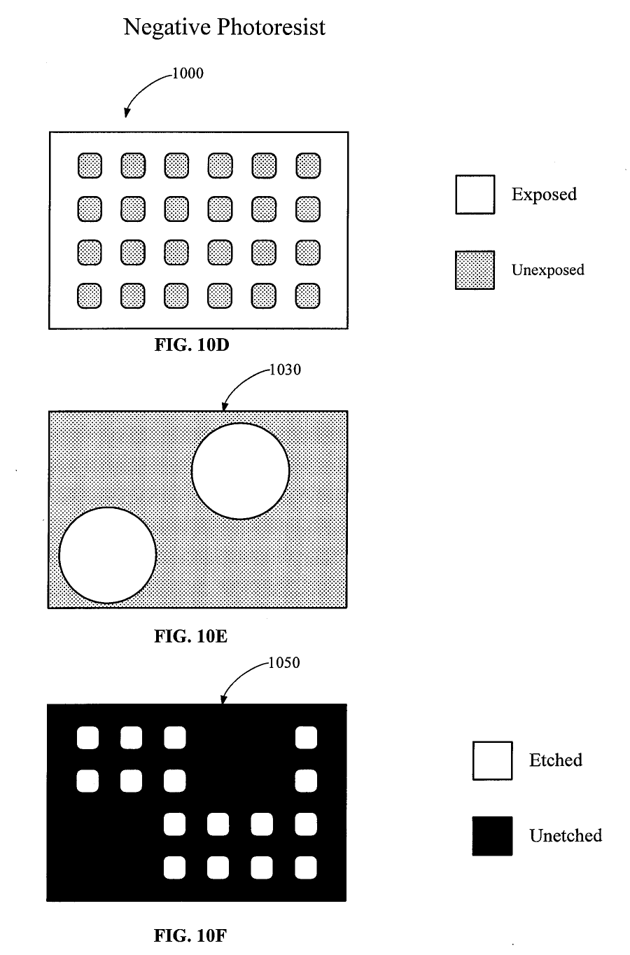

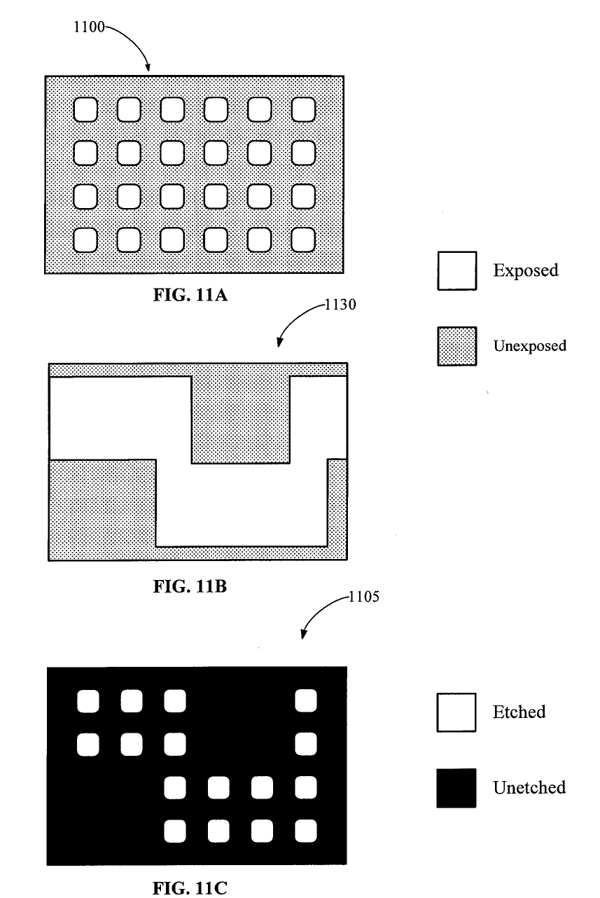

FIGS. 10A-10F compare the different latent exposure patterns using a positive photo resist compared with a negative photoresist. Turning first to FIG. 10A, a first latent exposure dot pattern 1000 is produced on a positive photoresist using, for example, one or more IL exposures. The dot pattern comprises a plurality of dots arranged substantially linearly in two dimensions. The dot pattern comprises a plurality of unexposed dots. In some embodiments, two orthogonal two-beam IL may be used to create the dot pattern shown in FIG. 10A. Other lithography techniques may also be used to create the first latent exposure pattern. The white portions are the exposed portions of the photoresists and the shaded portions are the unexposed portions of the photoresist. The second latent exposure pattern 1030 is provided during a second exposure. Various lithographic techniques may be used during the second exposure, for example, OPL and/or e-beam lithography. FIG. 10C shows the pattern resulting after post-exposure processing 1005. FIG. 10C shows a unique dot pattern. For example, the dots shown in FIG. 10C may be used to create a pattern of pads on a wafer.

FIG. 10D shows the same latent exposure dot pattern 1000 as shown in FIG. 10A. However, in this embodiment, a negative photoresist is used. The same second latent exposure pattern 1030 is used to expose the negative photoresist during the second exposure as shown in FIG. 10E. FIG. 10F shows the pattern resulting after post-exposure processing 1050. The white portions are developed and/or etched and the black portions are undeveloped or unetched after post-exposure processing, leaving a pattern of holes in the wafer. In some embodiments, this pattern of holes may also create vias and/or through holes.

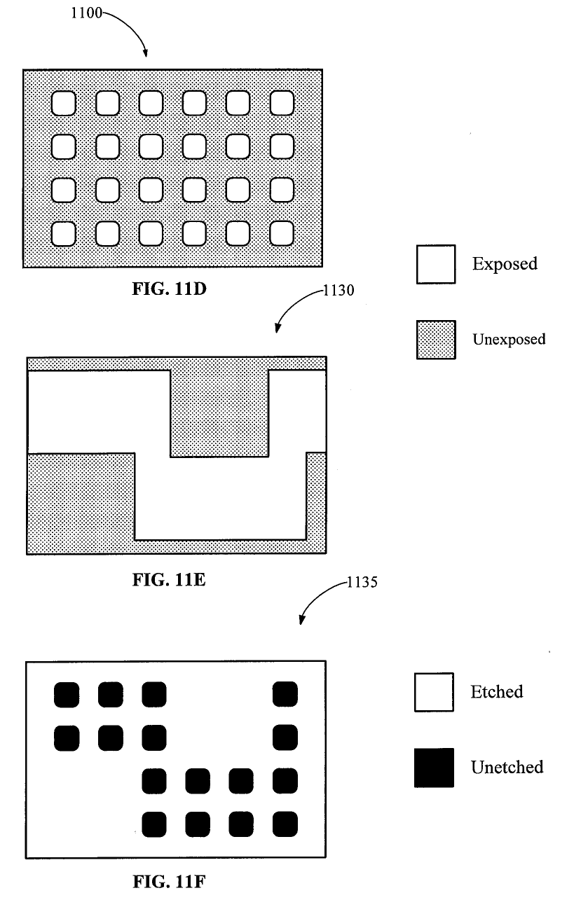

FIGS. 11A-11F also compare the latent exposure dot patterns using a positive non-linear photo resist compared with a negative non-linear photoresist. Turning first to FIG. 11A, a first latent exposure dot pattern 1100 is produced on a positive non-linear photoresist using, for example, one or more IL exposures. The white portions are the exposed portions of the photoresists and the shaded portions are the unexposed portions of the photoresist. In some embodiments, for example, this dot pattern is created using four-beam IL. In this embodiment, the dots are exposed to light, whereas, in FIGS. 10A and 10D the dots are unexposed. In some embodiments, the exposure provides less light than the exposure threshold of the nonlinear photoresist. Thus, without further exposure, the photoresist would be left substantially undeveloped during development. Other lithography techniques may also be used to create the first latent exposure pattern. The second latent exposure pattern 1130 is provided during a second exposure as shown in FIG. 11B. The second exposure similarly provides exposure less than the exposure threshold of the nonlinear photoresist. The combined exposure of the first exposure and the second exposure, however, may be greater than the nonlinear photoresist threshold. Hence, the photoresist is developed in portions where the photoresist is exposed in both exposures. Various lithographic techniques may be used during the second exposure, for example, OPL and/or e-beam lithography. FIG. 11C shows the pattern 1105 resulting after post-exposure processing. The white portions have been developed and the black portions are undeveloped after post-exposure processing, leaving a pattern of holes in the wafer. In some embodiments, this pattern of holes may also create vias and/or through holes.

FIG. 11D shows the same latent exposure dot pattern 1100 as shown in FIG. 11A. However, in this embodiment, a negative non-linear photoresist is used. The same second latent exposure pattern 1130 is used to expose the negative photoresist during the second exposure as shown in FIG. 11E. FIG. 11F shows the pattern resulting after post-exposure processing. FIG. 11F shows a unique dot pattern 1135. For example, the dots in shown in FIG. 11F may be used to create a pattern of pads on a wafer.

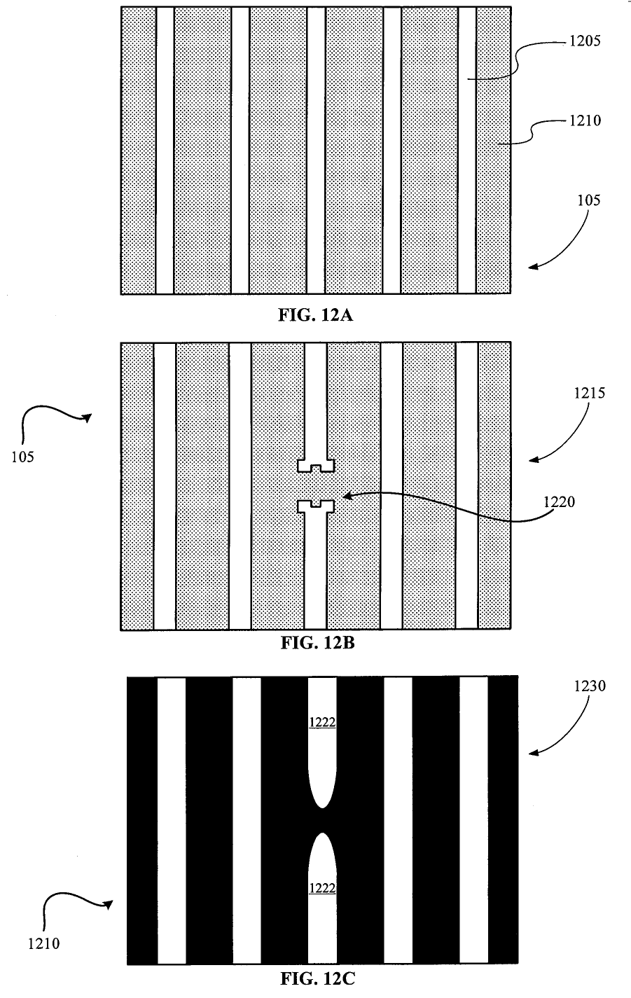

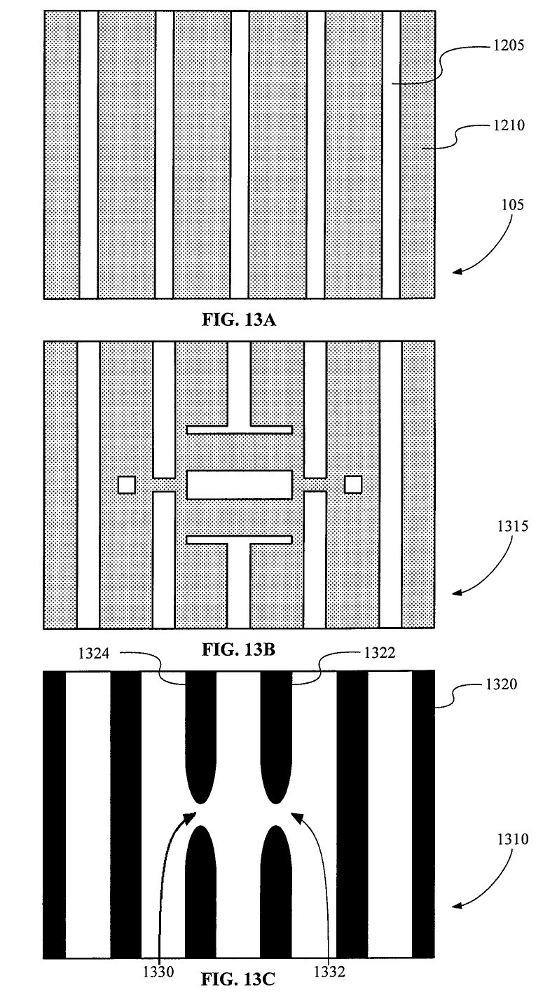

FIG. 12A shows a latent exposure line pattern 105 produced using, for example, an IL exposure on a positive resist. The latent exposure line pattern 105 includes a series of exposed portions 1205 and unexposed lines 1210. FIG. 12B shows a latent exposure pattern 1215 from a second exposure using a second lithography technique. This exposure includes an assist feature(s) 1220 used to create a line pattern that includes a break in one line on a substrate according to one embodiment. For example, resolution enhancement techniques may be used on an OPL mask to provide the assist feature. The odd pattern in the mask can be thought of as an optical trick for optical proximity correction. In some embodiments, for example, an optical mask similar to the latent exposure pattern shown in FIG. 12B may be used in an OPL exposure. While not intuitive, such patterns provide optimization of the resulting pattern as shown in FIG. 12C, which shows the line pattern 1230 resulting from the combination of the two exposures. The line pattern 1230 includes a number of lines and a break 1220 in the center line 1222 aligned with the assist feature in the second latent exposure line pattern 105. Various other assist features or resolution enhancement techniques may be used to optimize the final pattern and/or to optimize the angles. FIGS. 13A-15C show various other examples of assist features used during at least one exposure. The process described in relation to FIGS. 12A-12C may be used, for example, to create interconnects and/or portions of the gate layer.

FIG. 13A shows a latent exposure line pattern 105 produced using, for example, an IL exposure on a positive resist. The line pattern includes a series of exposed portions 1205 and unexposed lines 1210. A second exposure produces a second latent exposure line pattern 1315 with assist features as shown in FIG. 13B. In this embodiment, the assist features are designed to provide further exposure to the photoresist such that a cut between two lines is produced. In some embodiments, for example, an optical mask similar to the latent exposure pattern shown in FIG. 13B may be used in an OPL exposure. The composite pattern 1310 formed using the two exposures is shown in FIG. 13C. The resulting composite pattern 1310 includes a number of lines 1320 and includes gaps 1330, 1332 in two of the lines 1322, 1324. Various other assist features may be used to create the same cut in the lines. The process described in relation to FIGS. 13A-13C may be used, for example, to create interconnects and/or portions of the gate layer.

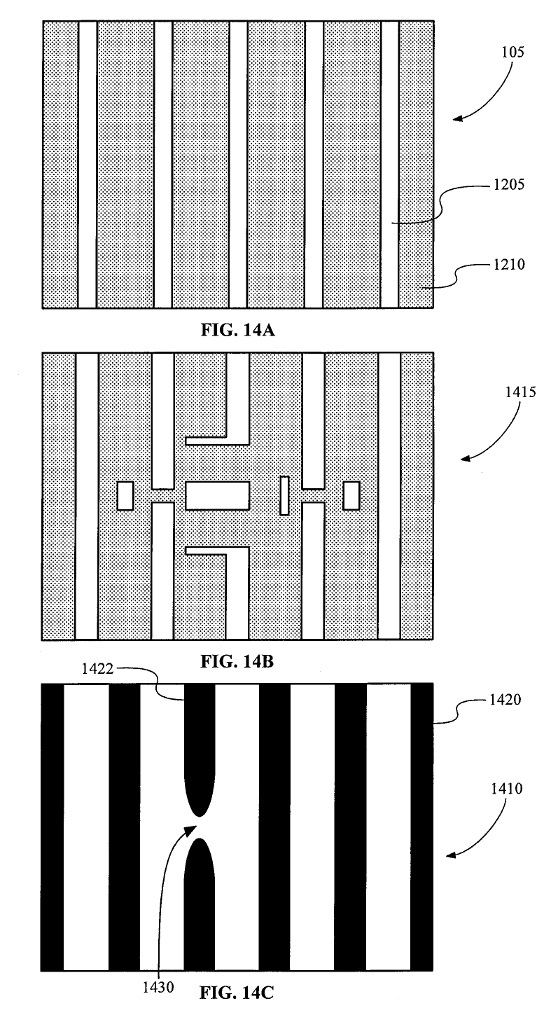

FIG. 14A shows another example of a latent exposure line pattern 105 produced using, for example, an IL exposure. The exposed portions 1205 are shown as white and the unexposed portions are shaded 1210. A second exposure produces a second latent exposure line pattern 1415 with assist features as shown in FIG. 14B. In this embodiment, the assist features are designed to provide further exposure to the photoresist such that a cut in a single line is produced. Note that the assist feature is not symmetric about the line being cut. In some embodiments, for example, an optical mask similar to the latent exposure pattern shown in FIG. 14B may be used in an OPL exposure. The composite line pattern 1410 shown in FIG. 14C includes a number of lines 1420 and a break 1430 in one line 1422. The process described in relation to FIGS. 14A-14C may be used, for example, to create interconnects and/or portions of the gate layer.

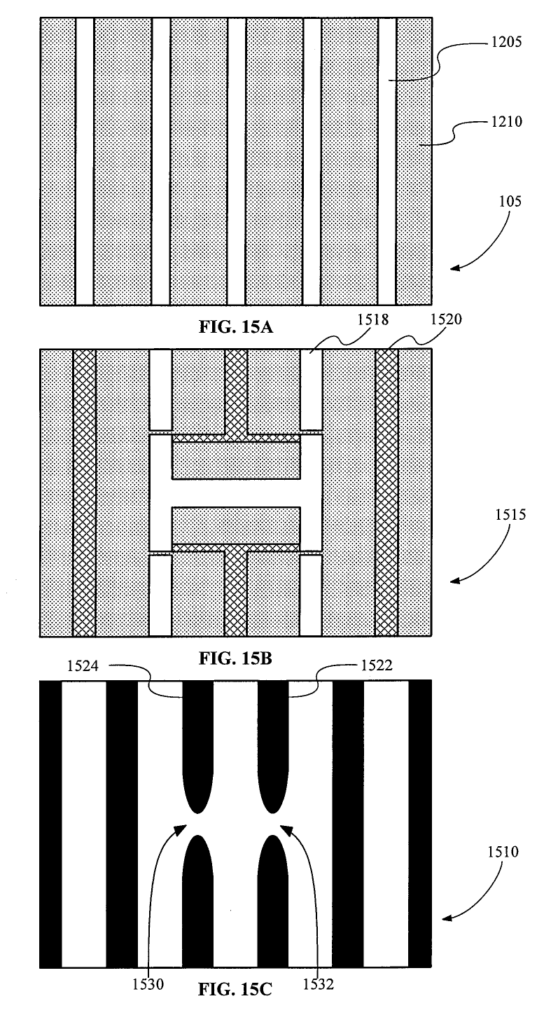

FIG. 15A shows another example of a latent exposure line pattern 105 produced using, for example, an IL exposure. The exposed portions 1205 are shown as white and the unexposed portions are shaded 1210. A second exposure produces a second latent exposure line pattern with assist features as shown in FIG. 15B. In this embodiment, OPL may be used with a phase-shift mask (PSM) 1515. Other lithographic techniques may also be used that add phase information to the exposure. The PSM 1515 may be an attenuated or alternating PSM. A PSM controls the phase of the light exposing the substrate and/or wafer which in turn provides a sharper intensity contrast. PSMs may provide not only amplitude information to the target but also provide phase information. A mask may permit light to pass with one phase through at 1518 and light of another phase to pass through at 1520. In some embodiments, PSMs may provide increased depth of focus. The composite image 1510, formed using the two exposures is shown in FIG. 15C. Two of the resulting lines 1522, 1524 have gaps 1530, 1532. The process described in relation to FIGS. 15A-15C may be used, for example, to create interconnects and/or portions of the gate layer.

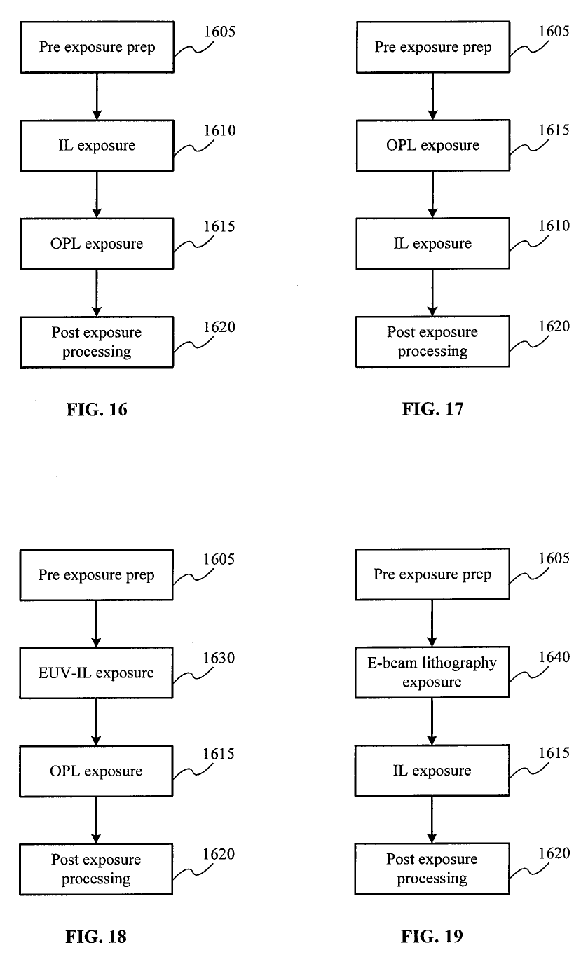

FIG. 16 shows a flowchart depicting one embodiment. A wafer, substrate or any other target undergoes pre-exposure preparation at step 1605. Those skilled in the art will recognize various processes that may occur within pre-exposure preparation. Various steps may be included in the pre-exposure preparation; for example, the photoresist may be provided, a pre-exposure bake may occur, various annealing steps may occur, a photoresist may be applied using any deposition technique, etc. The wafer may then be exposed using an IL interferometer at block 1610. The IL exposure may expose the wafer with a line pattern or a dot pattern. In some embodiments, the IL exposure may underexpose portions of the wafer. Following the IL exposure, the wafer may be exposed using OPL at block 1615. In some embodiments, the OPL exposure may include a mask with or without assist features. In some embodiments, the mask may comprise a PSM. The OPL exposure may provide more exposure dosage to portions of the wafer exposed during the IL exposure. In some embodiments, the combined dosage from the IL exposure and the OPL exposure may provide the proper exposure to a photoresist on the wafer. Following the OPL exposure, the wafer may undergo post-exposure processing at block 1620. Post-exposure processing may include baking, annealing, cleaning, developing, etching, washing, freezing, etc.

FIG. 17 shows a flowchart similar to the one shown in FIG. 16 with the OPL exposure 1615 and the IL exposure 1610 reversed according to another embodiment.

FIG. 18 shows a flowchart similar to the one in FIG. 16 with a first exposure comprising an EUV-IL exposure at block 1630 and a second exposure comprising an OPL exposure according to another embodiment.

FIG. 19 shows a flowchart similar to the one in FIG. 16 with a first exposure comprising an e-beam lithography exposure at block 1640 and an IL exposure 1615 as the second exposure according to another embodiment. In some embodiments, an existing e-beam lithography system may be retrofitted to include an IL system to provide the IL exposure. In various other embodiments, the IL exposure may occur on a wafer with a photoresist using an IL interferometer. The wafer may then be transferred to an e-beam lithography chamber. In some embodiments, IL exposure may provide a substantially regular line pattern or dot pattern and the e-beam exposure may provide, for example, assist features, breaks, tabs, bulges, additional exposure to increase line widths or pitch widths, holes, vias, etc.

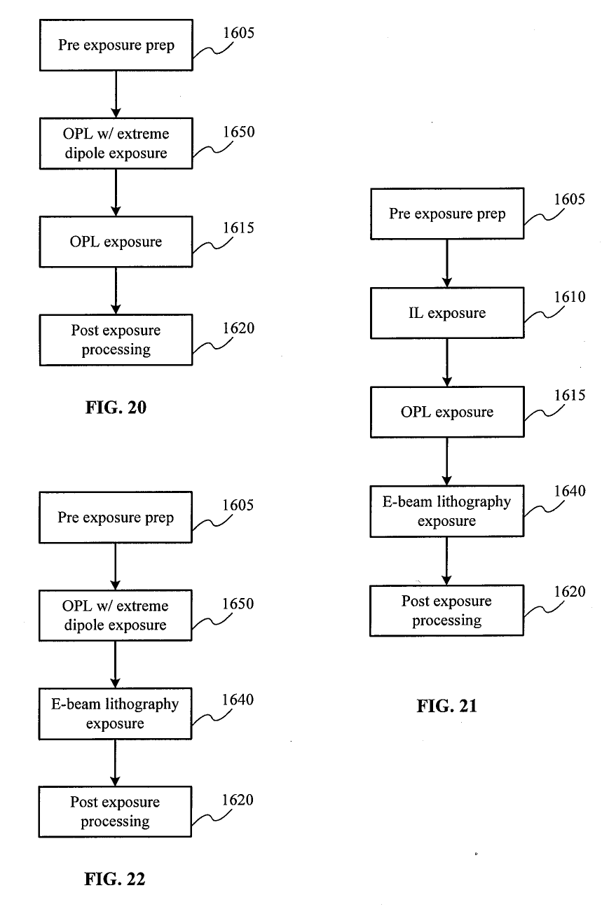

FIG. 20 shows a flowchart similar to the one in FIG. 16 with the first exposure comprising an OPL with extreme dipole exposure at block 1650 and the second exposure comprising an OPL exposure 1615 according to another embodiment.

FIG. 21 shows a flowchart similar to the one shown in FIG. 16 with an e-beam lithography exposure included in the process as a third exposure at block 1640 according to another embodiment. Of course, the order of the IL exposure 1610, the OPL exposure 1615, and the e-beam lithography exposure 1640 may be reversed or performed in any order. Moreover, any number of exposures using any type of lithography may be used without deviating from the spirit of the embodiments described herein. Also, some of the various exposures may underexpose some portions of the target.

FIG. 22 shows a flowchart similar to the one in FIG. 16 with a first exposure comprising an OPL with extreme dipole exposure at block 1650 and a second exposure comprising an e-beam lithography exposure at block 1640 according to another embodiment. Of course, the order of the e-beam lithography exposure at block 1640 and the OPL with extreme dipole exposure 1650 may be reversed.

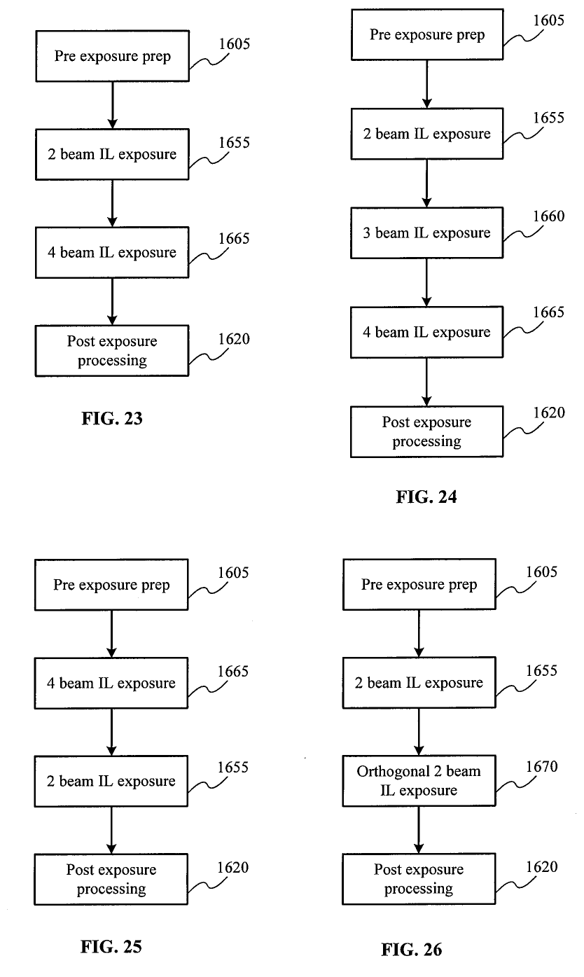

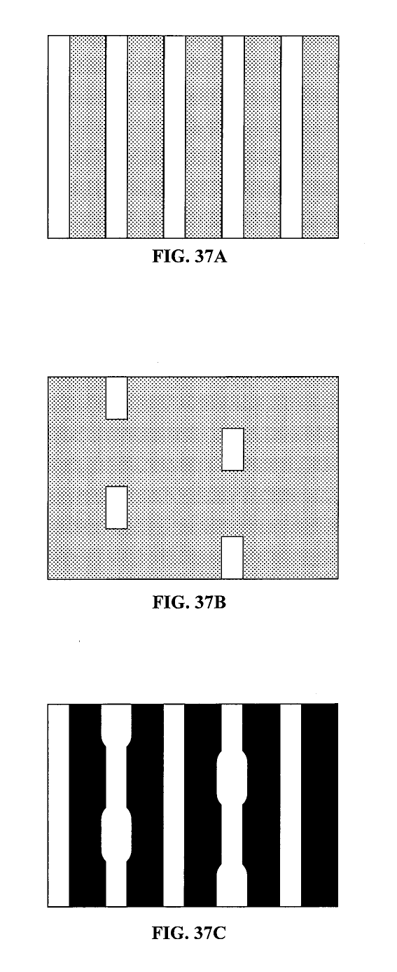

FIG. 23 shows a flowchart similar to the one in FIG. 16 with a first exposure comprising a two-beam IL exposure at block 1655 and a second exposure comprising a four-beam IL exposure at block 1665 according to another embodiment. In some embodiments, the two-beam IL exposure may provide a pattern of lines on the photoresist. The four-beam IL exposure, for example, may provide additional exposure at regular intervals within the lines provided in the two-beam exposure. The combined exposure may provide bulges in the lines as shown in FIG. 37C.

FIG. 24 shows a flowchart similar to the one in FIG. 16 with a first exposure comprising a two-beam IL exposure at block 1655, a second exposure comprising a three-beam IL exposure at block 1660 and a third exposure comprising a four-beam IL exposure at block 1665 according to another embodiment.

FIG. 25 shows a flowchart similar to the one in FIG. 16 with a first exposure comprising a four-beam IL exposure at block 1665 and a second exposure comprising a two-beam IL exposure according to another embodiment.

FIG. 26 shows a flowchart similar to the one in FIG. 16 with a first exposure comprising a two-beam IL exposure at block 1655, a second exposure comprising another two-beam IL exposure that is orthogonal to the first exposure at block 1670.

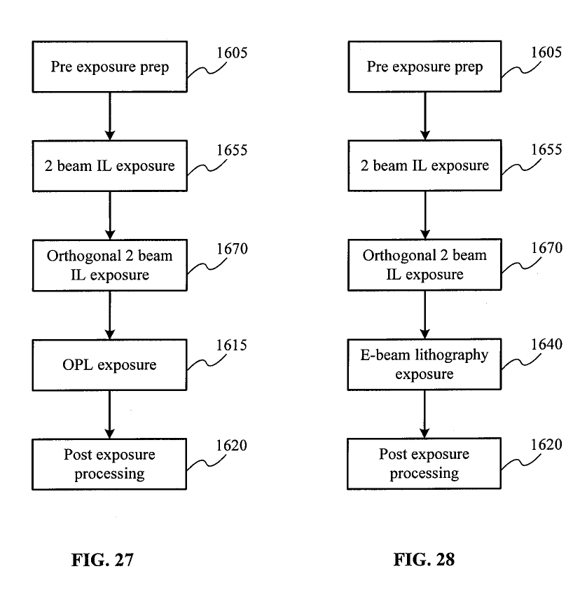

FIG. 27 shows a flowchart similar to the one in FIG. 16 with a first exposure comprising a two-beam IL exposure at block 1655, a second exposure comprising an orthogonal two-beam IL exposure at block 1670 and a third exposure comprising an OPL exposure at block 1615 according to another embodiment.

FIG. 28 shows a flowchart similar to the one in FIG. 16 with a first exposure comprising a two-beam IL exposure at block 1655, a second exposure comprising an orthogonal two-beam IL exposure at block 1670 and a third exposure comprising an e-beam lithography exposure at block 1640 according to another embodiment.

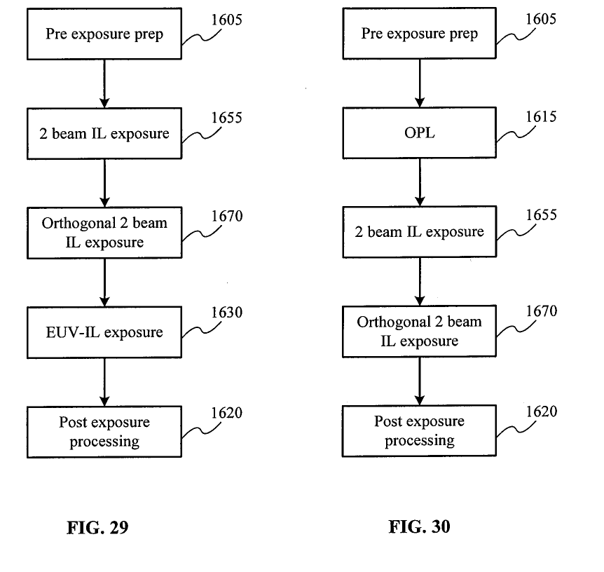

FIG. 29 shows a flowchart similar to the one in FIG. 16 with a first exposure comprising a two-beam IL exposure at block 1655, a second exposure comprising an orthogonal two-beam IL exposure at block 1670 and a third exposure comprising an EUV-IL at block 1630 according to another embodiment.

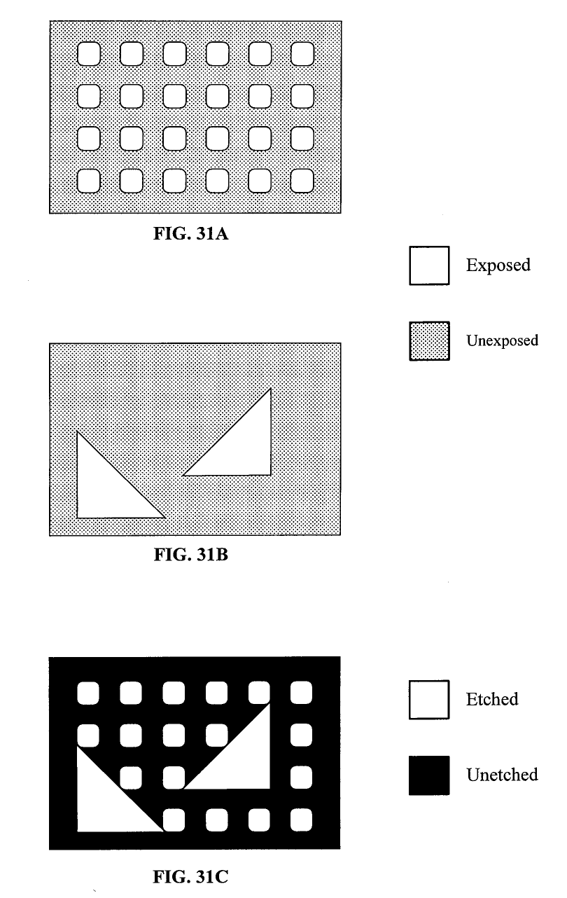

FIG. 30 shows a flowchart similar to the one in FIG. 16 with a first exposure comprising an OPL exposure, a second exposure comprising a two-beam IL exposure at block 1655, and a third exposure comprising an orthogonal two-beam IL exposure at block 1670 according to another embodiment.

While FIGS. 16-30 show flowcharts of processes using various combinations of exposures, these combinations are not limiting. Various other combinations of exposures using various lithographic techniques may be used without deviating from the scope and/or spirit of the embodiments described herein.

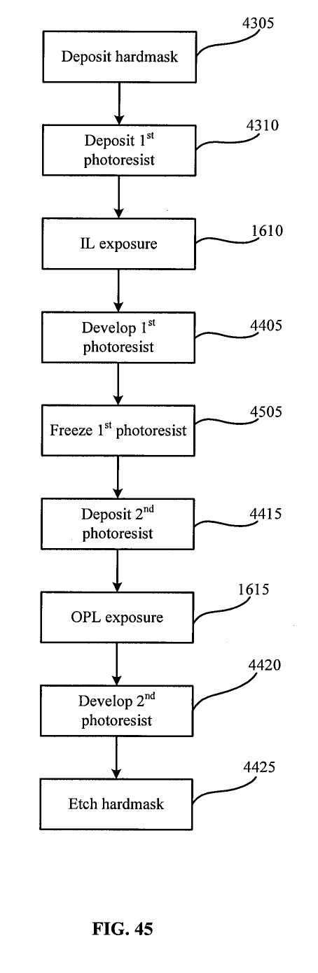

Moreover, in some of the embodiments described in FIGS. 16-30, some post-exposure processing may occur between exposures. For instance, FIGS. 16-30 show double or triple exposure processes. FIG. 44 shows a double patterning process similar to the double exposure process shown in FIG. 16. FIG. 45 shows a double patterning process with litho-freezing. Moreover, the multiple exposures may occur within a single chamber or within different chambers. In other embodiments, the exposures may occur with a relatively small interval between exposures. For example, less than an hour or within minutes of each other. In other embodiments, the exposures may occur after a longer period of time. For example, hours or days may lapse between exposures.

FIG. 31A shows a latent exposure dot pattern produced on a positive photoresist using, for example, an IL exposure. The IL exposure may be created using four-beam IL. The white portions are the exposed portions of the photoresists and the shaded portions are the unexposed portions of the photoresist. FIG. 311B shows a latent exposure pattern of a second exposure with triangle shapes. FIG. 31C shows a pattern resulting after the photoresist has been exposed with both exposures and following any post-exposure processing. Large triangular shaped holes result from the OPL exposure.

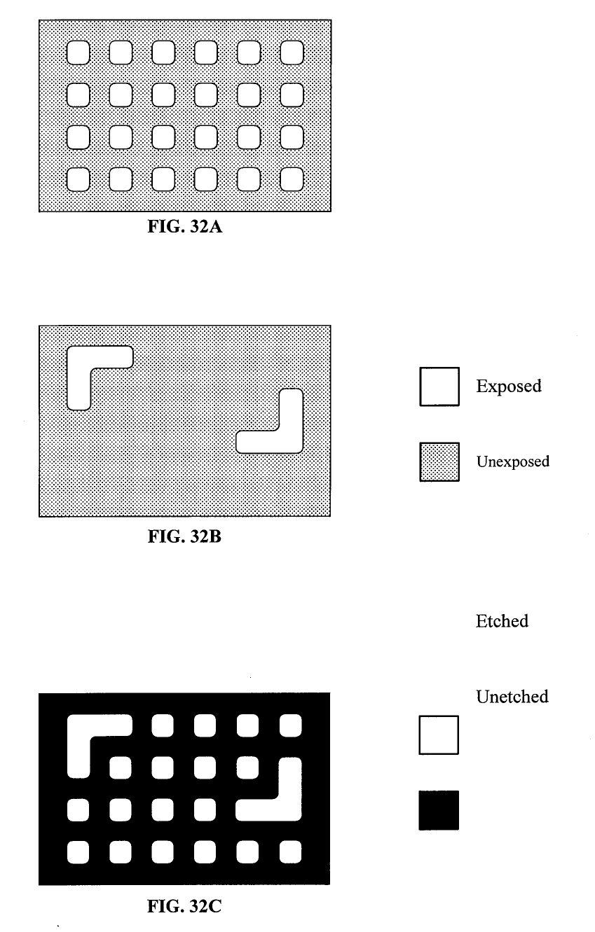

FIG. 32A shows a latent exposure dot pattern produced using IL, for example, with a positive photoresist. The IL exposure may be created, for example, using four-beam IL or two orthogonal two-beam IL exposures. FIG. 32B shows a latent exposure pattern of a second exposure providing exposure with L-shapes that overlap some of the dots in the first exposure. FIG. 32C shows the resulting hole pattern on the substrate with a positive photoresist using the IL exposure pattern shown in FIG. 32A and the second exposure shown in FIG. 32B according to one embodiment. The L-shaped holes may comprise pad or other electrical connectors within a layer.

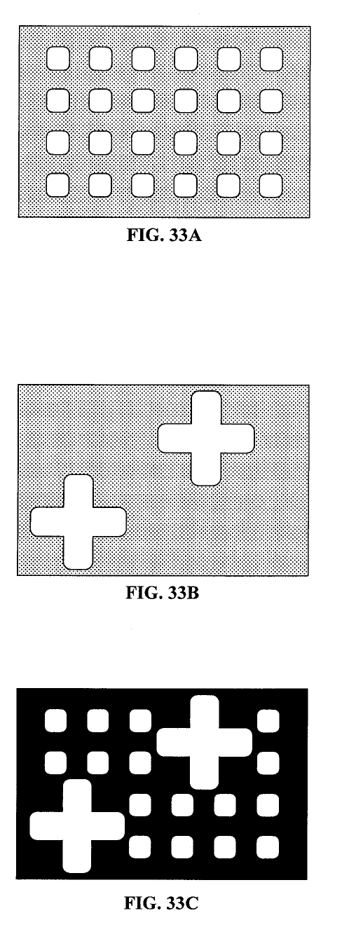

FIG. 33A shows a first latent exposure pattern produced using, for example, IL with a positive photoresist. A second latent exposure pattern is shown in FIG. 33B. For example, the second exposure may be created using OPL that uses an OPL mask with two cross shapes. As another example, e-beam lithography may also be used to produce the latent cross pattern shown in FIG. 33B. FIG. 33C shows the resulting hole pattern on the substrate with a positive photoresist using the exposure patterns shown in FIGS. 33A-33B.

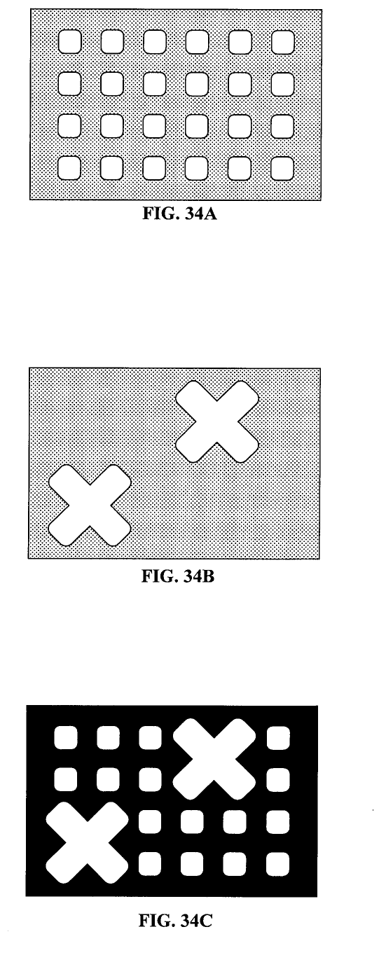

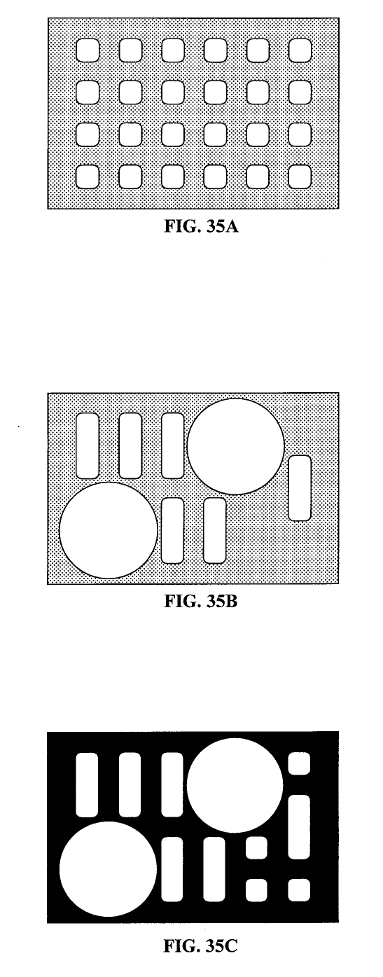

FIG. 34A shows a first latent exposure pattern produced using, for example, IL with a positive photoresist. The pattern may be created using a four-beam interferometer according to some embodiments. In other embodiments, the pattern may be created using a two-beam interferometer that makes two orthogonal passes at the wafer. FIG. 34B shows the latent exposure pattern for a second exposure. In some embodiments this exposure may be made using OPL with a mask with two X-shaped patterns. FIG. 34C shows the resulting hole pattern on the substrate using the IL exposure pattern shown in FIG. 34A and the second exposure shown in FIG. 34B according to one embodiment.

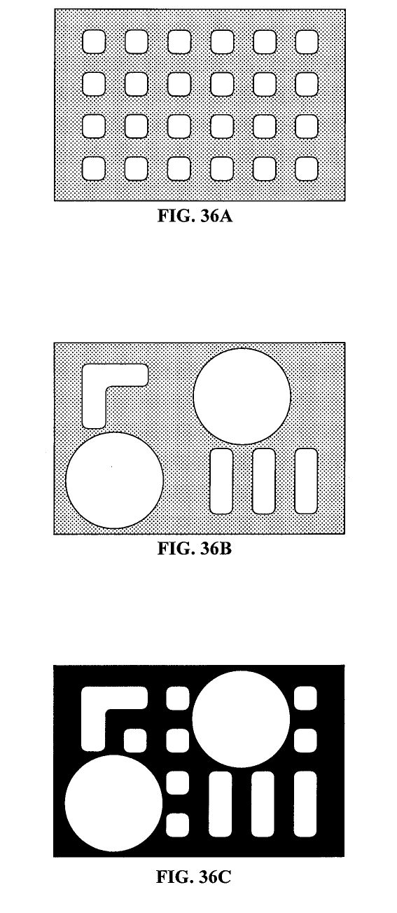

FIG. 35A shows a first latent exposure pattern produced using, for example, IL with a positive photoresist. FIG. 35B shows the latent exposure pattern for a second exposure. In some embodiments this exposure may be made using OPL with a mask with two X-shaped patterns. FIG. 35C shows the resulting hole pattern on the substrate using the IL line pattern shown in FIG. 35A and the second exposure shown in FIG. 35B according to one embodiment.

FIG. 36A shows a first latent exposure pattern produced using IL with a positive photoresist. FIG. 36B shows a latent exposure from a second exposure with a series of different shapes used to expose the substrate in coordination with the IL hole pattern shown in FIG. 36A. FIG. 36C shows the resulting hole pattern on a substrate using the IL line pattern shown in FIG. 36A and the second exposure shown in FIG. 36B according to one embodiment.

FIG. 37A shows a first latent exposure pattern produced using, for example, an IL exposure. FIG. 37B shows a latent exposure from a second exposure with assist features used to expose the substrate in coordination with the IL line pattern shown in FIG. 37A. FIG. 37C shows the composite pattern with bulges in the lines on the substrate using the exposure shown in FIG. 37A and the second exposure shown in FIG. 37B according to one embodiment. The process described in relation to FIGS. 37A-37C may be used, for example, to create landing pads.

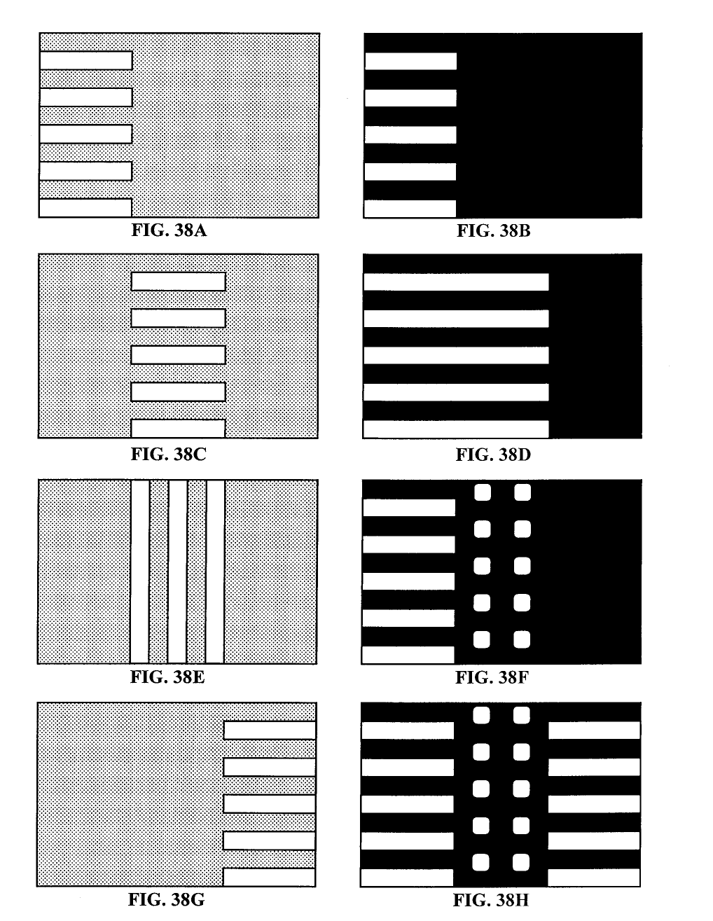

FIGS. 38A-38H show various latent images and patterns that may be created using a two-beam IL system on a substrate. FIG. 38A shows a first latent exposure pattern of a horizontal line pattern on the left most third of a substrate produced using, for example, a first IL exposure. FIG. 38B shows the resulting pattern on the substrate using the IL exposure shown in FIG. 38A according to one embodiment. FIG. 38C shows a latent exposure pattern of a horizontal line pattern on the middle third of the substrate produced using, for example, a first IL exposure. FIG. 38D shows the resulting pattern on the substrate using the IL exposures shown in FIGS. 38A and 38C according to one embodiment. FIG. 38E shows another latent exposure pattern of a vertical line pattern on the middle third of a substrate that is perpendicular to the pattern shown in FIG. 35C. FIG. 38F shows the resulting IL exposure. FIG. 38G shows a latent exposure pattern of a horizontal line pattern on the right most third of a substrate produced using, for example, a fourth IL exposure. FIG. 38H shows the resulting pattern on the substrate using the IL exposures shown in FIGS. 38A, 38C, 38E and 38G according to one embodiment. The process described in relation to FIGS. 38A-38H may be used, for example, to create DRAM and/or flash layers.

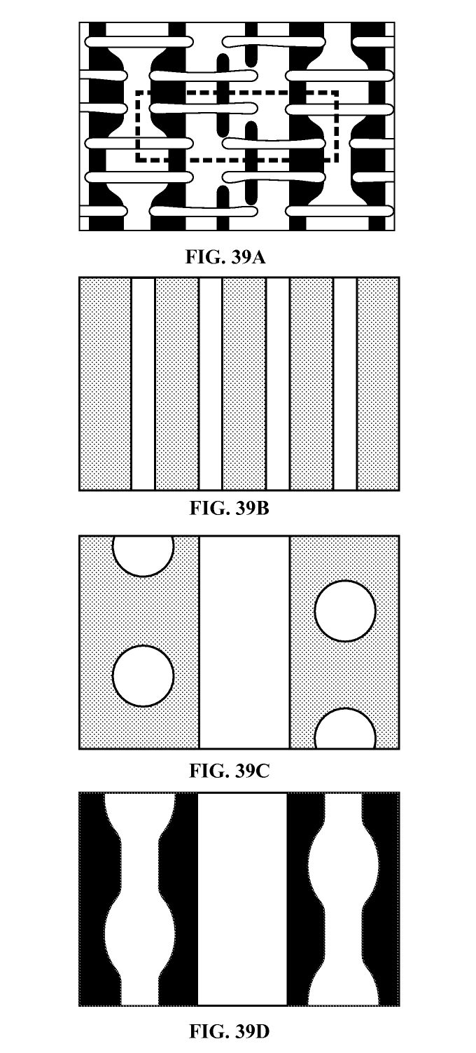

FIG. 39A shows an image of various semiconductor features that may be created using embodiments disclosed herein. FIG. 39B shows a latent exposure pattern produced using, for example, a two-beam IL exposure. FIG. 39C shows a latent exposure from a second exposure that exposes the substrate in coordination with the IL line pattern shown in FIG. 39B. The second exposure may be provided, for example, using four-beam IL. FIG. 39D shows the composite pattern with bulges on a substrate using the exposure shown in FIG. 39B and a second exposure shown in FIG. 39C according to one embodiment. The second exposure may be created using, for example, four-beam IL. In some embodiments, the bulges in the lines generate a pad on which subsequent vias can land. In such embodiments, these pads allow for some amount of misalignment and provide higher yield than if there was no pad, in which case the alignment would have to be perfect. FIGS. 39A-39C may be used, for example, to create landing pads.

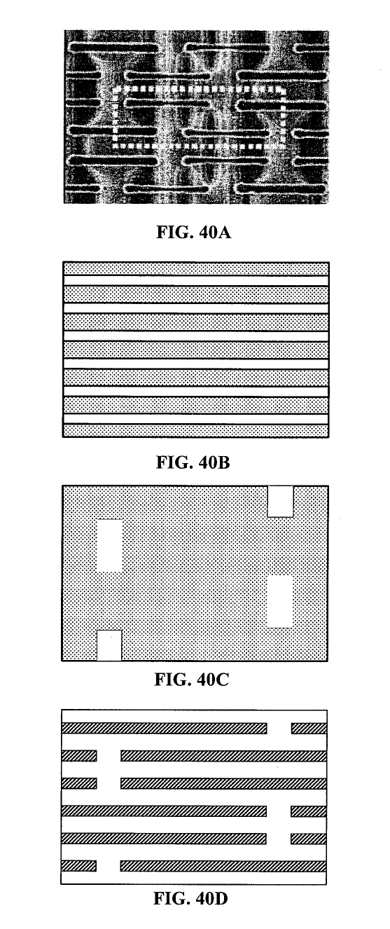

FIG. 40A shows an image of an SRAM cell with multiple layers. The line patterns of any of the layers of the SRAM cell may be created using various embodiments described herein. FIGS. 40B-40C show photolithography steps that may be used to produce the gate layer of the features shown in this image. FIG. 40B shows a latent exposure pattern produced using, for example, an IL exposure. FIG. 40C shows latent exposure pattern created during a second exposure in coordination with the IL line pattern shown in FIG. 40B. FIG. 40D shows the composite pattern corresponding to the gate layer shown in FIG. 40A using the exposure shown in FIG. 40B and second exposure shown in FIG. 40C according to one embodiment. FIGS. 40A-40C may be used, for example, to create interconnects and/or portions of a gate layer.

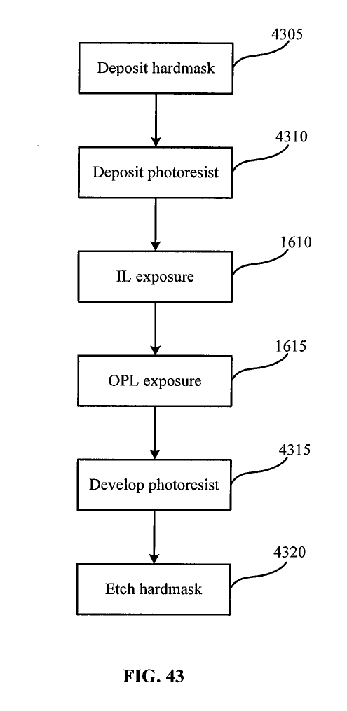

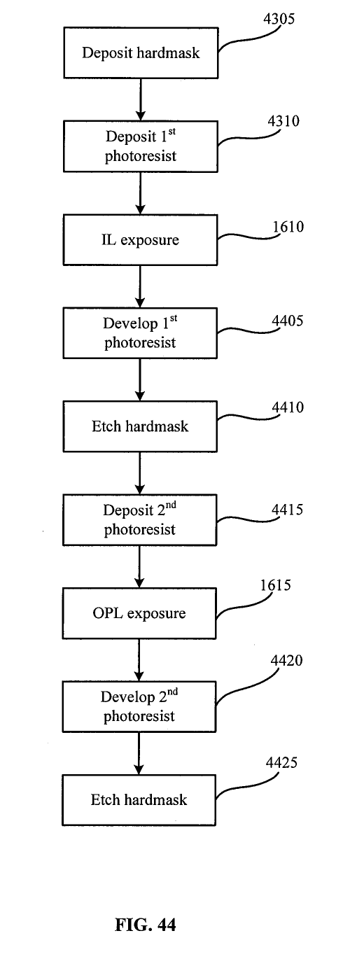

FIG. 43 shows a more detailed flowchart of a double exposure process like the one shown in FIG. 16. A hardmask layer is deposited on a substrate and/or a device layer at block 4305. A photoresist is then deposited on the hardmask at block 4310. In some embodiments pre-exposure baking may occur before after, and/or in between these depositions. An IL exposure may then occur at block 1610, followed by an OPL exposure at block 1615. Following the exposures, the photoresist is developed at block 4315. After development, the underlying layer, hardmask layer, and/or device layer, may then be etched (either dry or wet) at block 4320. Post-exposure bakes may also occur before etching the hardmask. While these details are shown in conjunction with FIG. 16 using IL and OPL, any of the flowcharts shown and described in FIGS. 17-30 may be used without limitation.

FIG. 44 shows a flowchart of a double patterning process according to one embodiment. In this embodiment, a hardmask and a first photoresists are deposited in blocks 4305 and 4310. An IL exposure than occurs at block 1610. The first photoresist may then be developed at block 4405 followed by an etching process (dry or wet) at block 4410 that etches the underlying layer, such as a hardmask and/or a device layer. Following the developing, a bake or anneal may occur before the etching in some embodiments. At block 4415 a second photoresist is deposited. This second photoresist may then be exposed using OPL at block 1615. The second photoresist may then be developed at block 4420 followed by an etching process (dry or wet) at block 4425 that etches the underlying layer, such as a hardmask, and/or a device layer. While these details are shown in conjunction with FIG. 16 using IL and OPL, any of the flowcharts shown and described in FIGS. 17-30 may be used without limitation.

FIG. 45 shows a double patterning process with litho-freezing according to some embodiments. In this embodiment, a hardmask and a first photoresists are deposited in blocks 4305 and 4310. An IL exposure may then occur at block 1610. The first photoresist may then be developed at block 4405. Following development of the first photoresist the first photoresist may then be frozen at block 4505, so that the first photoresist will not be sensitive to the second exposure. The freezing may be a thermal curing and/or a coating of freezing material. After the freeze, a second photoresist is deposited at block 4415. This second photoresist may then be exposed using OPL at block 1615. The second photoresist may then be developed at block 4420 followed by an etching process (dry or wet) at block 4425 that etches the underlying layer, such as a hardmask, and/or a device layer. While these details are shown in conjunction with FIG. 16 using IL and OPL, any of the flowcharts shown and described in FIGS. 17-30 may be used without limitation.

In some embodiments, freezing a photoresist can include covering the developed pattern in the first photoresist with chemical freezing materials, such as a freezing agent that may prevent damage to the photoresist from a second litho process. In some embodiments, The freezing agent may include resin, crosslinker, and/or a casting solvent.

A number of multiple exposure lithography systems and/or methods have been described according to various embodiments. In some embodiments, photoresists are used that include a dosage threshold. This dosage threshold defines the amount of light needed to properly expose and develop the photoresist. In some embodiments, for example, both the first exposure and the second exposure provide dosage less than the dosage threshold of the photoresist; however, the combined dosage may be greater than the dosage threshold. In other embodiments, one of the exposures provides dosage greater than the dosage threshold and the other exposure provides dosage less than the dosage threshold. In yet other embodiments, both the first exposure and the second exposure independently provide dosage greater than the dosage threshold.

Interference Lithography

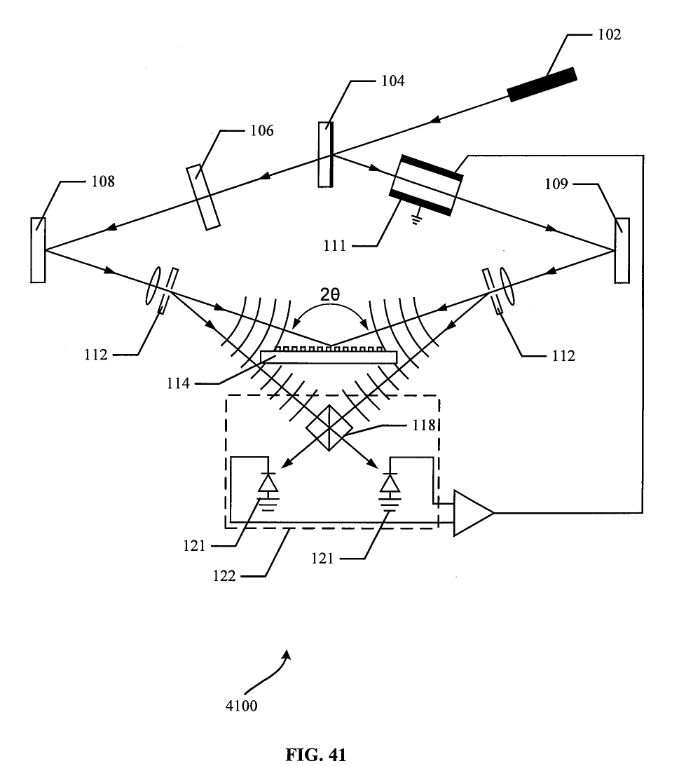

FIG. 41 shows a block diagram of an interference lithography system 4100 according to one embodiment. A laser 102 produces a coherent light beam that is split at a beam splitter 104 into two-beams. The laser 102, for example, may comprise an excimer laser. Various other light sources may also be used, for example LEDs broadband sources with a filter, etc. Other light sources may include UV light source from gas-charged lamps such as Hg-lamp at g-line (436 nm) and i-line (365 nm), or EUV light sources at 13.5 nm wavelength from a magnetron or Tin plasma.

Excimer lasers may produce light at various ultraviolet wavelengths. For example, an excimer laser may include an Ar₂ laser producing light with a wavelength of 126 nm, a Kr₂ laser producing light with a wavelength of 146 nm, an F₂ laser producing light with a wavelength of 157 nm, an Xe₂ laser producing light with a wavelength of 172 or 175 nm, an ArF laser producing light with a wavelength of 193 nm, a KrF laser producing light with a wavelength of 248 nm, an XeBr laser producing light with a wavelength of 282 nm, an XeCl laser producing light with a wavelength of 308 nm, an XeF laser producing light with a wavelength of 351 nm, a KrCl laser producing light with a wavelength of 222 nm, a Cl₂ laser producing light with a wavelength of 259 nm, or a N₂ laser producing light with a wavelength of 337 nm. Various other lasers operating in other spectral bands may also be used without deviating from the scope of the present disclosure. The various embodiments provided herein will be described using an ArF excimer laser that produces light at 193 nm.

The two beams created at the beam splitter 104 are reflected toward a target 114 using two mirrors 108, 109. Absent a substrate or other material, the target 114 may be a process chuck. The target may hold a substrate or other material. The beam splitter 104, may include any light splitting element, such as a prism or diffraction grating. The two beams interfere constructively and destructively at the target 114 creating an interference pattern at the target 114. The position of the interference pattern may depend on the phase difference of the two beams. The angle θ is the angle of incidence of a single beam with respect to the normal of the target 114. The angle 2θ is the angle between the two beams at the substrate.

Spatial filters 112 may be included along each beam path. These spatial filters 112 may expand the beams for dose uniformity over a large area. Moreover, the spatial filters 112 may be used to remove spatial frequency noise from the beams. Due to the potential of relatively long propagation distances (˜1 m) and the lack of additional optics after the spatial filer, the beams interfering at the substrate can be accurately approximated as spherical. Other optical elements may be employed throughout the optical paths of the two beams of light.

The spatial position of the interference fringes is determined by the relative phase of the beams, which makes this type of interferometer extremely sensitive to path length differences between the two arms. For this reason, a phase difference sensor 122 may be employed in conjunction with a Pockels cell 111 in one arm of the interference lithography system 4100. The phase difference sensor 122 may include another beam splitter 118 and two photodiodes 121. Differential changes in the intensity on the photodiodes 121 may be converted into phase differences. The phase difference may then be adjusted at the Pockels cell 111. A variable attenuator 106 in the arm that does not have the Pockels cell 111 may be employed to balance any power lost through the Pockels cell 111.

The Pockels cell 111 may include any device that includes a photo refractive electro-optic crystal and/or a piezoelectric element that can change the polarization and/or phase of a light beam in response to an applied voltage. The phase may be changed by varying the index of refraction of the Pockels cell in response to the applied voltage. When a voltage is applied to this crystal it can change the phase of the light beam. In some Pockels cells, the voltage, V, required to induce a specific phase change, 0, can be calculated, for example, by the following equation:

$$V = \frac{φ}{π} {V}_{\frac{λ}{2}} ,$$

where

$${V}_{\frac{λ}{2}}$$

is the half wavelength voltage, which depends on the wavelength, λ, of the light beam passing through the Pockels cell. The Pockels cell may comprise, for example, an oxide of bismuth and germanium or of bismuth and silicon. Most importantly, the Pockels cell may include any device or material that may tune the phase of light in the presence of an applied voltage.

The Pockels cell may be replaced with an optical element that varies the optical path distance through the optical element. The optical path distance through the optical element may be change by rotating the optical element or by flexing the width of the optical element. The optical path distance may change using a mechanical devices or piezoelectrics. To induce a 180° phase change, for example, the optical element should increase the optical path distance by:

$$d = \frac{λ}{2 n} ,$$

where n is the index of refraction of the optical element. Accordingly, change in distance by either rotating the optical element or flexing is a fraction of the wavelength of the light beam passing through the optical element.

In various embodiments, the phase difference between the first exposure and the second exposure is not necessarily 180°. For example, a phase difference of 121° may be used between three exposures. Moreover, a phase difference of 90° may be used between four exposures. In other embodiments, various other phase differences between various exposures may be used to vary the width or placement of exposed portions of the nonlinear photoresist.

The Pockels cell may be used to align the phases of the two light beams within the interferometer as well as to adjust the phase difference between the two light beams so that they are 180° out of phase.

FIG. 1B illustrates a latent or real image of a latent exposure line pattern 105 of spaces 120 (exposed to light) and lines 110 (not exposed to light) produced by the interference lithography apparatus 4100 of FIG. 41 on the surface of the target 114. “Latent” refers to a pattern on a photoresist which experienced a chemical reaction due to radiation but has not yet been developed in a solution to remove the exposed areas of the positive tone photoresist. The lines 110 have a substantially equal width. The spaces 120 may or may not have a width equal to the width of the lines 110.

The pitch is a sum of a line width 110 and a space width 120 as shown in FIG. 1B. The minimum half pitch (HP) is a measure of the pitch which can be resolved by a projection optical exposure apparatus with a pre-determined wavelength λ and numerical aperture (NA). Minimum HP may be expressed as:

$$HP = \frac{( {k}_{1} \frac{λ}{{n}_{1}} )}{NA}$$

where NA is the numerical aperture of a projection lens in the lithography tool, n₁ is the refractive index of a media between the substrate and the last element of the optical projection system, and k₁ is Rayleigh's constant. Some optical projection systems currently in use for microlithography use air, for which n₁=1. For liquid immersion microlithographic systems, n₁>1.4. For n₁=1, HP may be expressed as:

$$HP = \frac{{k}_{1} λ}{NA} .$$

Using an ArF excimer laser the wavelength, λ, is 193 nm. A minimum k₁ value is approximately 0.28 and the NA may be approximately 1. Accordingly, the smallest HP achievable with such a system may be approximately 54 nm and is often referred to as Rayleigh's limit. Other systems employing such things as immersion lithography may bring HP near 32 nm. Various embodiments may provide an HP less than 32 nm.

In another embodiment, the target 114 includes a photoresist with nonlinear, super-linear or memoryless properties. Such a photoresist may have a limited response period. The photoresist may be a thermal photoresist. The terms memoryless photoresist, nonlinear photoresist, super-linear photoresist, and thermal photoresist may be used interchangeably throughout this disclosure despite not being perfectly synonymous. Such photoresists may be broadly characterized by the fact that the photoresist does not integrate energies of consecutive exposures, as long as none of the energy exceeds a threshold, and there is a time period (or sufficient cool-down time) between them. Moreover, nonlinear photoresists may only integrate energies of incident light as long as the incident light exceeds a threshold.

The intensity of light, I₁₂, incident at the target 114 using the interferometer shown in FIG. 41 can be written as:

I₁₂=I₁+I₂+2(\vec{E}₁·\vec{E}₂)cos └(\vec{k}₁−\vec{k}₂)·\vec{r}+Δφ┘,

where I₁ and I₂ are the intensities of light from the first and second arms of the interferometer, \vec{E}₁ and \vec{E}₂ are the first and second electric fields associated with the incident light, and \vec{k}₁ and \vec{k}₂ are the respective wave vectors. Furthermore, \vec{r} is the position vector and Δφ is the phase difference of the two incident beams of light. Intensity maxima is found when the cosine term equals zero:

(\vec{k}₁−\vec{k}₂)·\vec{r}+Δφ=0.

A two-beam interference pattern may include a series of lines where the photoresist is not exposed to light and a series of spaces where the photoresist is exposed to light with a positive photoresist and vice-versa with a negative photoresist. By carefully controlling the phase difference between the two incident beams of light so that a second exposure uses a phase difference that is about 180° different from the first phase difference, the interferometer may expose the surface of the target with a plurality of substantially parallel lines.

Electron Beam Lithography

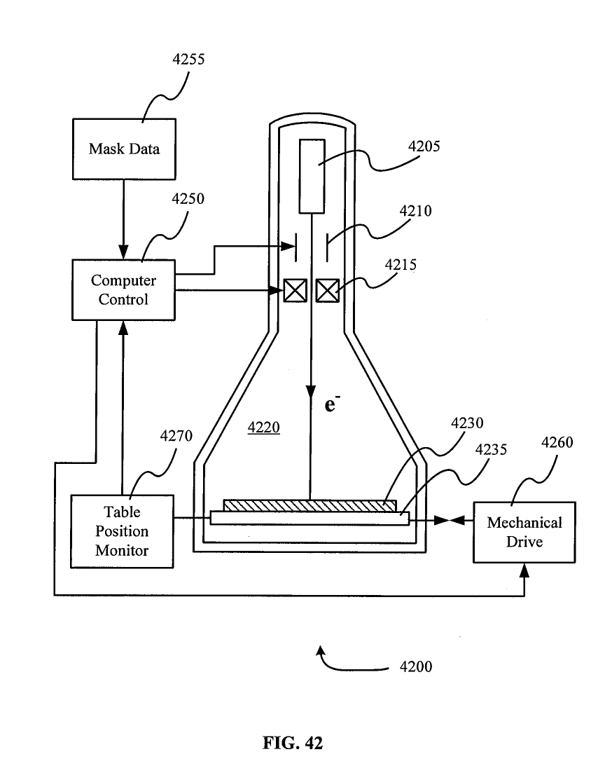

FIG. 42 shows a diagram of an electron beam apparatus 4200 that may be used in some embodiments. An electron source or gun 4205 is shown positioned above a target 4230 within a vacuum chamber 4220. The target may include a substrate with any number of labels, such as a photoresist layer. The target may rest on a mechanical table 4235. The electron source 4205 may be, for example, a tungsten thermionic source, an LaB₆ source, cold field emitter, or a thermal field emitter. Various electron optics may also be included, for example, one or more lenses, a beam deflector 4215, a blanker for turning the beam on and off 4210, a stigmator for correcting any astigmatism in the beam, apertures for helping to define the beam, alignment systems for centering the beam in the column, and/or an electron detector for assisting with focusing and locating marks on the sample.

The electron beam apparatus 4200 may include a beam deflector 4215 to scan the electron beam across the target 4230. The beam deflector 4210 may be magnetic or electrostatic. In some embodiments, coils or plates may be used to magnetically or electrostatically deflect the electron beam. For example, four deflectors may be placed around the electron beam to deflect the electron beam toward positions on the target 4230.

The electron beam apparatus 4200 may also include beam blankers 4210 used to turn the beam on or off. The beam blankers 4210 may include electrostatic deflector plates that deflect the electron beam away from the target 4230. In some embodiments, one or both of the plates may be coupled with an amplifier with a fast response time. To turn the beam off, a voltage is applied across the plates which sweeps the beam off axis.

Control of the electron beam may be directed by a computer 4250 or any other processing machine. The computer 4250 may receive mask data 4255 from any source. The mask data 4255 describes coordinates of the desired incidence of the electron beam. The computer 4250 may use the mask data 4255 to control the beam deflectors 4215, the beam blankers 4210 and/or the mechanical drive 4260 that is coupled with the mechanical table 4235. Signals may be sent to the beam deflectors 4215 to control the deflection of the electron beam so that it is pointed at a specific location on the table. A table position monitor 4270 may be used to detect the relative position of the mechanical table and inform the computer accordingly.

What is claimed is:

1. A method for exposing a wafer comprising:
exposing a first plurality of substantially parallel lines on the wafer using interference lithography during a first exposure, wherein the first exposure provides a first dosage to the first plurality of substantially parallel lines; and
exposing second portions of the wafer using a second lithographic technique during a second exposure, wherein the second exposure provides a second dosage to the second portions of the wafer.

2. The method according to claim 1, wherein the second portions of the wafer overlap at least part of the first portions of the wafer, wherein those portions of the wafer that overlap with the first portion and the second portion are exposed with the first and the second dosage.

3. The method according to claim 1, wherein the second lithographic technique is selected from the group comprising electron beam lithography, EUV lithography, interference lithography, and optical photolithography.

4. The method according to claim 1, further comprising optimizing the first dosage based on the second dosage.

5. The method according to claim 1, further comprising optimizing the exposure rate of the first exposure based on the exposure rate of the second exposure.

6. The method according to claim 1, further comprising optimizing the second exposure based on the first dosage.

7. The method according to claim 1, further comprising optimizing the exposure rate of the second exposure based on the exposure rate of the first exposure.

8. The method according to claim 1, wherein the second lithography technique comprises optical photolithography that provides a mask with at least one assist feature.

9. The method according to claim 1, further comprising:
providing a photoresist on the wafer; and
developing the photoresist following both the first exposure and the second exposure.

10. The method according to claim 1, further comprising:
providing a first photoresist on a hardmask layer of the wafer;
developing the first photoresist following the first exposure and before the second exposure;
etching the hardmask layer to transfer the pattern provided during the first exposure into the hardmask layer;
providing a second photoresist on the wafer prior to the second exposure;
developing the second photoresist following the second exposure; and
etching the hardmask layer to transfer the pattern provided during the second exposure into the hardmask layer.

11. The method according to claim 1, further comprising:
providing a first photoresist on a hardmask layer of the wafer;
developing the first photoresist following the first exposure and before the second exposure;
freezing the first photoresist layer so that the first photoresist will not be sensitive to the second exposure;
providing a second photoresist on the wafer prior to the second exposure;
developing the second photoresist following the second exposure; and
etching the hardmask layer to transfer the pattern provided during the first exposure and the second exposure into the hardmask layer.

12. The method according to claim 1, further comprising providing a negative photoresist, and wherein the second portions include at least one line that is substantially perpendicular to the plurality of substantially parallel lines, wherein at least after the developing the at least one line joins two of the plurality of substantially parallel lines.

13. The method according to claim 1, further comprising providing a positive photoresist on the wafer; and wherein the second portions include at least one line that is substantially perpendicular to the plurality of substantially parallel lines, wherein at least after the developing the at least one line divides at least one of the plurality of substantially parallel lines.

14. The method according to claim 1, further comprising providing a positive photoresist on the wafer; and wherein the second portions include at least one line that substantially overlaps a portion of the plurality of substantially parallel lines, wherein at least after the developing the at least one line bulges at least one of the plurality of substantially parallel lines.

15. The method according to claim 1, further comprising providing a positive photoresist on the wafer; and wherein the second portions include at least one line that substantially overlaps a portion of the plurality of substantially parallel lines, wherein at least after the developing the at least one line trims at least one of the plurality of substantially parallel lines.

16. The method according to claim 1, further comprising providing a positive photoresist on the wafer; and wherein the second portions include at least one line that is substantially perpendicular to a portion of the plurality of substantially parallel lines, wherein at least after the developing the at least one line adds a tab to at least one of the plurality of substantially parallel lines.

17. The method according to claim 1, developing the wafer following both the first exposure and the second exposure.

18. A system for exposing a wafer, comprising:
a two-beam interference lithography interferometer configured to expose the wafer using interference lithography during a first exposure, wherein the first exposure provides a plurality of substantially parallel lines of a first exposure dose on the wafer; and
a lithographic scanner configured to expose the wafer during a second exposure, wherein the second exposure provides a second exposure dose on portions of the wafer.

19. The system according to claim 18, wherein the second scanner comprises an optical photolithography scanner that includes a mask with at least one assist feature.

20. The system according to claim 18, wherein the second scanner comprises an optical photolithography scanner that is configured to underexpose at least a portion the wafer.

21. The system according to claim 18, wherein the interferometer is configured to underexpose at least a portion of the wafer.

22. The system according to claim 18, further comprising a chamber, wherein both the interferometer and the lithographic scanner are housed within the chamber.

23. The system according to claim 18, further comprising a first chamber and a second chamber, wherein the interferometer is housed within the first chamber, and the lithographic scanner is housed within the second chamber.

24. A photolithography system, comprising:
interference lithography means for exposing a wafer using interference lithography techniques, wherein the exposure provides a plurality of substantially parallel lines of a first exposure dose on the wafer;
lithography means for exposing the wafer using a lithography technique, wherein the exposure provides a second exposure dose on portions of the wafer; and
post processing means for developing portions of the wafer.

25. A method for exposing a wafer, comprising:
providing a photoresist on the wafer;
exposing the wafer with a first exposure according to a first exposure pattern using interference lithography, wherein the first exposure pattern includes a plurality of substantially parallel lines, wherein the first exposure pattern is configured to expose the wafer at the plurality of substantially parallel lines, and wherein the first exposure provides a first dosage to portions of the wafer;
exposing portions of the wafer using an optical photolithography system that includes a mask, wherein the exposure provides a second dosage on portions of the wafer; and
developing the photoresist after both the first exposure and the second exposure.
